(19) United States
(12) Patent Application Publication
(10) Pub. No.: US 2025/0149395 A1
(43) Pub. Date: May 8, 2025

(54) POWER MODULES HAVING ENCAPSULATION STRESS AND STRAIN MITIGATING CONFIGURATIONS

(71) Applicant: WOLFSPEED, INC., Durham, NC (US)

(72) Inventors: Utkarsh Mehrotra, Fayetteville, AR (US); Brandon Passmore, Fayetteville, AR (US); Vrej Barkhordarian, Glendale, CA (US)

(21) Appl. No.: 18/501,858

(22) Filed: Nov. 3, 2023

(51) Int. Cl. H01L 23/31; H01L 23/00; H01L 23/373; H01L 25/065

(52) U.S. Cl. CPC H01L 23/3121; H01L 23/3737; H01L 24/48; H01L 24/85; H01L 25/0652; H01L 2224/48139; H01L 2224/48157; H01L 2224/85447; H01L 2224/85801; H01L 2924/13091; H01L 2924/18165

(57) ABSTRACT

A power module includes at least one power substrate; a plurality of power devices on at least one power substrate; power contacts; power wire bonds; and a composite physical containment structure having a composite element and an encapsulation material. The composite element may include a membrane structure, a dam structure and/or a glob structure; and a portion of the composite physical containment structure is arranged at least partially on the plurality of power devices, the power wire bonds, and/or the at least one power substrate.

### STATEMENT REGARDING FEDERALLY SPONSORED RESEARCH OR DEVELOPMENT

This invention was made with Government support by the United States United Air Force Research Lab under DoD Contract FA8650-21-C-2600. The United States government has certain rights in the invention.

### BACKGROUND OF THE DISCLOSURE

### 1. Field of the Disclosure

This disclosure is directed to power modules having encapsulation stress and strain mitigating configurations. Moreover, the disclosure is directed to a process of configuring power modules having encapsulation stress and strain mitigating configurations.

### 2. Related Art

As will be appreciated by those skilled in the art, power modules are known in various forms. Power modules provide a physical containment for power components, usually power semiconductor devices. These power semiconductors are typically soldered or sintered on a power electronic substrate. The power module typically carries the power semiconductors, provides electrical and thermal contact, and includes electrical insulation. However, the physical containment of typical power modules fails to effectively prevent moisture ingress and/or the physical containment of typical power modules has limited thermal conductivity.

Accordingly, what is needed is a physical containment for a power module to limit moisture ingress and/or provide improved thermal conductivity.

### SUMMARY OF THE DISCLOSURE

In one aspect, a power module includes at least one power substrate. The power module also includes a plurality of power devices on at least one power substrate. The power module furthermore includes power contacts. The power module in addition includes power wire bonds. The power module moreover includes a composite physical containment structure having a composite element and an encapsulation material. The power module also includes where the composite element may include a membrane structure, a dam structure and/or a glob structure. The power module furthermore includes where a portion of the composite physical containment structure is arranged at least partially on the plurality of power devices, the power wire bonds, and/or the at least one power substrate.

In one aspect, a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a composite element and an encapsulation material. The process also includes arranging a portion of the composite physical containment structure at least partially on the plurality of power devices, the power wire bonds, and/or the at least one power substrate. The process furthermore includes where the composite element may include a membrane structure, a dam structure and/or a glob structure.

In one aspect, a power module includes at least one power substrate. The power module also includes a plurality of power devices on at least one power substrate. The power module furthermore includes power contacts. The power module in addition includes power wire bonds. The power module moreover includes a housing having at least housing sidewalls. The power module also includes a composite physical containment structure having a membrane structure; and an encapsulation material. The power module furthermore includes where the encapsulation material is arranged within the housing sidewalls.

In one aspect, a power module includes at least one power substrate. The power module also includes a plurality of power devices on at least one power substrate. The power module furthermore includes power contacts. The power module in addition includes power wire bonds. The power module moreover includes a composite physical containment structure having a dam structure and an encapsulation material. The power module also includes where the dam structure is filled with a dam encapsulation material. The power module furthermore includes where the dam encapsulation material and the encapsulation material may include different materials having different material properties.

In one aspect, a power module includes at least one power substrate. The power module also includes a plurality of power devices on at least one power substrate. The power module furthermore includes power contacts. The power module in addition includes power wire bonds. The power module moreover includes a composite physical containment structure having a glob structure and an encapsulation material. The power module also includes where the glob structure and the encapsulation material may include different materials having different material properties.

In one aspect, a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a membrane structure and an encapsulation material. The process also includes providing a housing having at least housing sidewalls. The process furthermore includes arranging the encapsulation material within the housing sidewalls.

In one aspect, a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a dam structure and an encapsulation material. The process also includes filling the dam structure with a dam encapsulation material. The process furthermore includes configuring and structuring the dam encapsulation material and the encapsulation material with different materials having different material properties.

In one aspect, a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a glob structure and an encapsulation material. The process also includes configuring and structuring the glob structure and the encapsulation material with different materials having different material properties. The process furthermore includes arranging a portion of the composite physical containment structure at least partially on the plurality of power devices, the power wire bonds, and/or the at least one power substrate.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a partial top view of a power module according to aspects of the disclosure.

FIG. 2 illustrates a partial top view of the power module according to FIG. 1 with components removed.

FIG. 3 illustrates a partial cross-section view of the power module according to FIG. 1.

FIG. 4 illustrates a partial perspective cross-section view of the power module according to FIG. 1.

FIG. 5 illustrates a partial cross-section of the power module according to FIG. 1.

FIG. 6 illustrates a partial cross-section of the power module according to FIG. 1.

FIG. 7 illustrates a partial top view of a power module according to FIG. 1.

FIG. 8 illustrates a partial perspective cross-section view of the power module according to FIG. 1.

FIG. 9 illustrates a top view of the membrane structure according to aspects of the disclosure.

FIG. 10 illustrates a partial perspective view of the power module according to FIG. 1.

FIG. 11 illustrates a perspective view of the power module according to FIG. 1.

FIG. 12 illustrates a top view of another implementation of the membrane structure according to aspects of the disclosure.

FIG. 13 illustrates a top view of another implementation of the membrane structure according to aspects of the disclosure.

FIG. 14 illustrates a partial perspective view of another implementation of the composite physical containment structure of the power module according to aspects of the disclosure.

FIG. 15 illustrates a top view of the composite physical containment structure according to FIG. 14.

FIG. 16 illustrates another perspective view of the composite physical containment structure according to FIG. 14.

FIG. 17 illustrates a cross-sectional view of the composite physical containment structure according to FIG. 14.

FIG. 18 illustrates a partial perspective view of another implementation of the composite physical containment structure of the power module according to aspects of the disclosure.

FIG. 19 illustrates a top view of the composite physical containment structure according to FIG. 18.

FIG. 20 illustrates another perspective view of the composite physical containment structure according to FIG. 18.

FIG. 21 illustrates a cross-sectional view of the composite physical containment structure according to FIG. 18.

FIG. 22 shows an exemplary process of making a power module 700 according to the disclosure.

FIG. 23 illustrates a partial exploded perspective view of a power module according to aspects of the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

Related power modules utilize silicone gels for physical containment. However, the disclosed power module utilizes epoxy encapsulants, which have one third the percentage moisture absorption compared to silicone gels, higher thermal conductivity and a greater hardness, along with lower density, greater modulus, etc. Further, epoxy encapsulants offer firmer support to wire bonds, terminals, and/or the like. Thus, the disclosed epoxy encapsulation as an alternative to silicone gel in power modules has the potential to increase power cycling life of the power module, make the power module more robust, and/or the like. Further, the disclosed epoxy encapsulation may allow for implementation of lidless case power modules. The disclosed epoxy encapsulation may also suppress moisture ingress, which allows the power module to pass moisture reliability tests such as Temperature Humidity Bias (THB) tests, Biased Highly Accelerated Stress Tests (BHAST), High Humidity, High Temperature Reverse Bias (H3TRB) tests, HV-H3TRB, THB-60, and/or the like. In this regard, reducing moisture ingress may reduce a rate of Ag dendrite growth.

However, the hardness and brittleness of the epoxy encapsulation material and bulk-inter epoxy bonds exerts stress on the power devices causing die crack, wire bond heel break, and/or the like during thermal shock. In this regard, bulk-inter epoxy bonds relates to the atomic structures of the epoxy material creating internal structures within the material. Further, wire bond heel break relates to a wire foot remaining attached to the power device and a remaining part of the wire breaking away.

To mitigate this issue, the disclosure describes at least three different composite approaches to control a volume fill inside the power module and stress-strain on the power device, other components, internal interfaces, and/or the like in the power module by altering the encapsulation geometry with a motivation to reduce the stress and reinforce the encapsulation matrix of the power module. The three different composite approaches are described below:

Utilizing a membrane that can be part of the housing body or can be standalone. For example, the membrane may be dropped in during power module build. The design of the membrane can be optimized per case module design and a shape of the strain reduction features can be multi-sided and is not limited to a square or a rectangle. For example, Hexagon, pentagon, circles, and/or the like. Different non-conductive and HT (high temperature) stable materials not limited to housing plastic can be used for the construction of the membrane.

Glob top power devices and dam and fill where the case module may use both epoxy and silicone gel encapsulation. The power devices may be epoxy globed. In this regard, epoxy encapsulation materials are ideal candidates for a material of the glob as the viscosity of the material can be temperature controlled.

Dam and fill may be utilized with a high viscosity material used to create a dam, which is filled with epoxy encapsulation. In aspects, the rest of the power module may be silicone filled. In this case, the intent may be to protect the power device from moisture ingress and support the wire bonds to enhance PC (power cycling) lifetime and at the same time filling a bulk of the module with silicone gel limiting the epoxy volume fill to minimize the stress-strain on the power device.

Related technology uses silicone gel for encapsulating power devices in case modules. The disclosure utilizes epoxy encapsulants in the power modules and provides improved power cycling life, the ability to operate in extreme environmental conditions as evidenced by passing a HV-H3TRB test, a H2S test, and/or other extreme environment conditions and adds mechanical strain relief for external electrical connections. In this regard the disclosure describes methods and/or configurations such as a membrane in housing, a glob top, and a dam and fill that allows integration of epoxy encapsulation in power modules.

Aspects of the disclosed technology may improve power cycling life, the ability to operate in extreme environmental conditions as evidenced by passing a HV-H3TRB test, a H2S test, and/or other extreme environment conditions of power modules. Aspects of the disclosed technology improve mechanical strain relief for external electrical connections of power modules.

Aspects of the disclosed technology may utilize a membrane that can be made with lighter weight material, integrated into the housing with the intent to reduce the volume of the silicone gel encapsulation translating to weight density improvements of case modules. Aspects of the disclosed technology may be applicable to all case modules for power modules implementing different voltage nodes, structures, configurations, and/or the like.

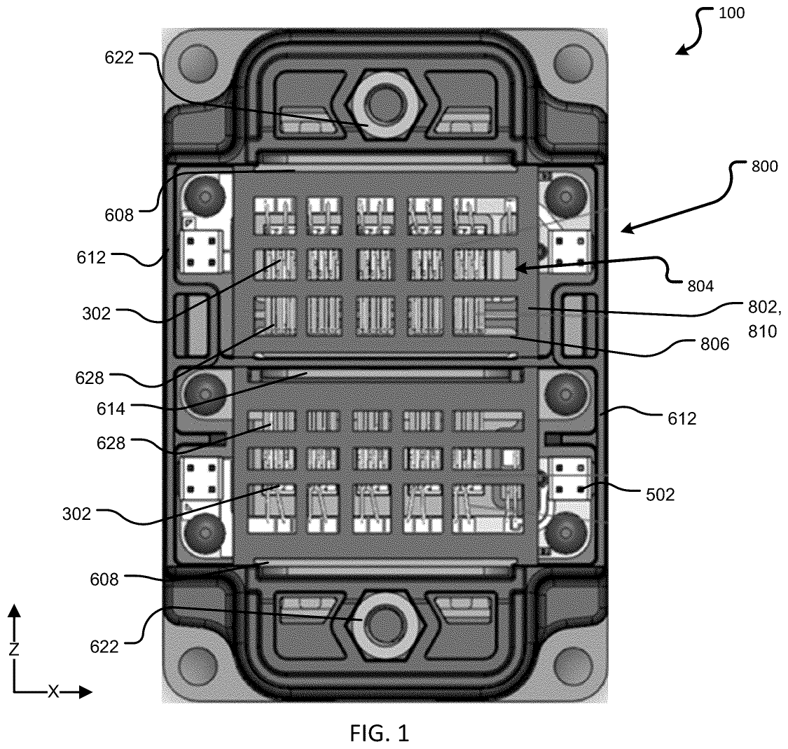

FIG. 1 illustrates a partial top view of a power module according to aspects of the disclosure.

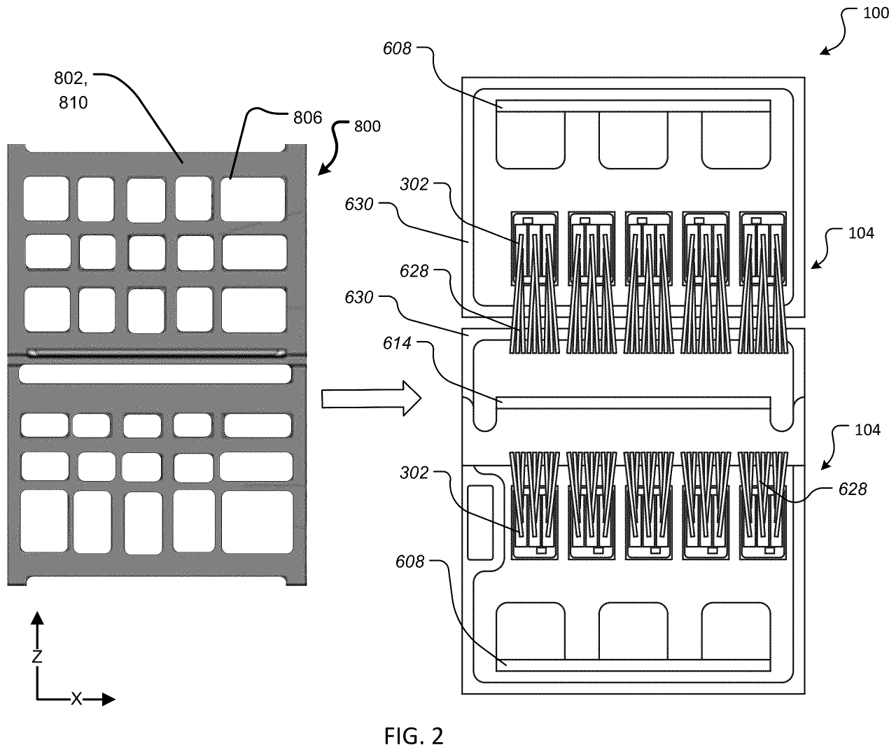

FIG. 2 illustrates a partial top view of the power module according to FIG. 1 with components removed.

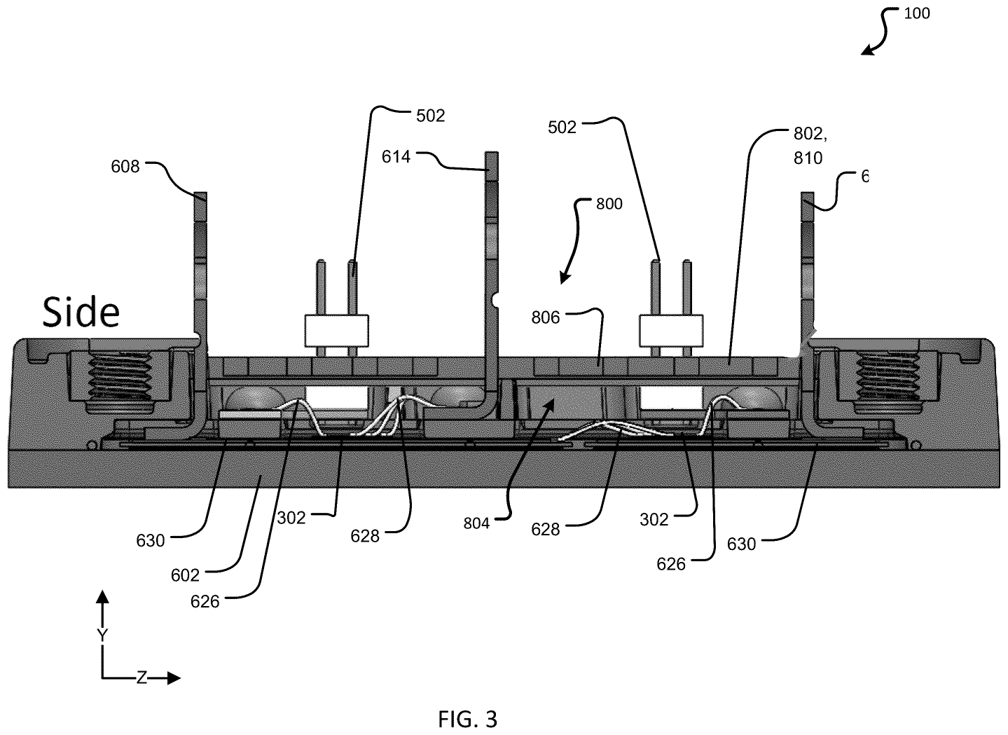

FIG. 3 illustrates a partial cross-section view of the power module according to FIG. 1.

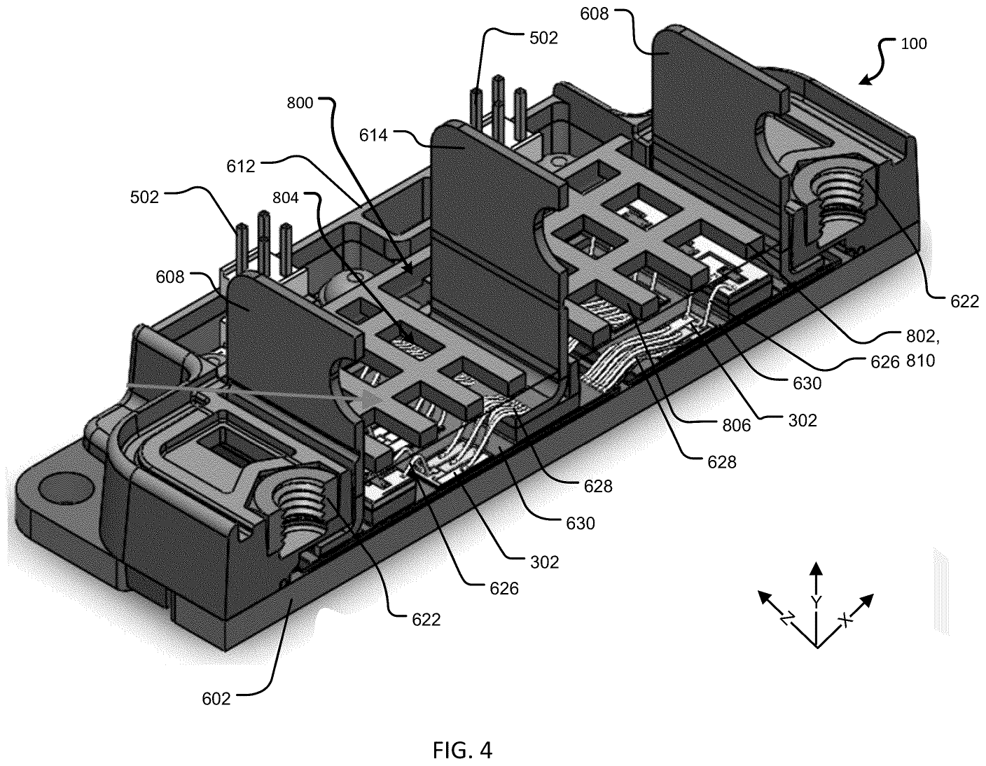

FIG. 4 illustrates a partial perspective cross-section view of the power module according to FIG. 1.

In particular, FIG. 1 illustrates a power module 100 that may include power devices 302, power contacts 608 that may be implemented as edge power contacts, housing sidewalls 612, a power contact 614 that may be implemented as a center power contact, power wire bonds 628 and/or the like. However, the power module 100 may include numerous configurations with fewer or different elements than those described herein. In this regard, FIG. 1 illustrates the power module 100 open and the power contacts 608 and the power contact 614 arranged prior to final manufacturing processing.

Additionally, the power module 100 includes a composite physical containment structure 800. In aspects, the composite physical containment structure 800 may include a composite element 810 and an encapsulation material 804.

In aspects, the composite element 810 may include a membrane structure 802. Accordingly, in aspects the composite physical containment structure 800 may include the membrane structure 802 and the encapsulation material 804. In other aspects, the composite element 810 may include other implementations as described herein.

In aspects, the membrane structure 802 may be arranged above the power devices 302 and the power wire bonds 628. Further, the membrane structure 802 may be arranged between the housing sidewalls 612. Additionally, the membrane structure 802 may be arranged between the power contacts 608. Further the membrane structure 802 may be arranged on either side of the power contact 614.

In aspects, the membrane structure 802 may include aperture portions 806 arranged therein. Additionally, the membrane structure 802 may be configured as a single structure. However, in other implementations the membrane structure 802 may include multiple structures and/or multiple implementations of the membrane structure 802.

In aspects, the encapsulation material 804 may be arranged at least partially on the power devices 302, may be arranged at least partially directly on the power devices 302, may be arranged completely on the power devices 302, may be arranged completely directly on the power devices 302, and/or the like.

In aspects, the encapsulation material 804 may be arranged at least partially on the power wire bonds 628, may be arranged at least partially directly on the power wire bonds 628, may be arranged completely on the power wire bonds 628, may be arranged completely directly on the power wire bonds 628, and/or the like.

Additionally, the encapsulation material 804 may extend from the power devices 302 and/or the power wire bonds 628 up to the membrane structure 802. In aspects, the encapsulation material 804 may extend from the power devices 302 and/or the power wire bonds 628 up to the membrane structure 802, into the membrane structure 802, through the membrane structure 802, above the membrane structure 802, and/or the like. In this regard, the encapsulation material 804 is shown as transparent for illustration and ease of understanding of the components of the power module 100. However, the encapsulation material 804 may be implemented as a non-transparent material.

Further, the encapsulation material 804 may extend from the power devices 302 and/or the power wire bonds 628 up to the aperture portions 806. In aspects, the encapsulation material 804 may extend from the power devices 302 and/or the power wire bonds 628 up to the aperture portions 806, into the aperture portions 806, through the aperture portions 806, above the aperture portions 806, and/or the like.

The encapsulation material 804 may be injection molded, dispensed, and/or the like, and may be applied in the aperture portions 806, a groove in the housing sidewalls 612, and/or the like and compressed between the housing sidewalls 612 and the at least one power substrate 630. In aspects, the encapsulation material 804 may be dispensed by a dispensing device.

In aspects, the membrane structure 802 may occupy a large percentage volume within the power module 100 in comparison to a volume of the encapsulation material 804 within the power module 100. In aspects, the membrane structure 802 may occupy 20%-50% of a volume within the power module 100 with respect to a volume of the encapsulation material 804 within the power module 100. In aspects, the membrane structure 802 may occupy 20%-30%, 30%-40%, or 40%-50% of a volume within the power module 100 with respect to a volume of the encapsulation material 804 within the power module 100.

FIG. 2 further illustrates the power module 100 prior to installation of the membrane structure 802 over the power devices 302 and the power wire bonds 628; and prior to installation of the encapsulation material 804 over the power devices 302 and the power wire bonds 628. As further illustrated in FIG. 2, the power module 100 may include at least one power substrate 630. Additionally, FIG. 2 illustrates an exemplary arrangement of the power devices 302, the power wire bonds 628, and the at least one power substrate 630.

FIG. 3 further illustrates the power module 100 and the membrane structure 802 arranged over the power devices 302 and the power wire bonds 628. As further illustrated in FIG. 3, the power module 100 may include a base plate 602 and signal connections 626.

Additionally, the encapsulation material 804 may be arranged at least partially on at least one power substrate 630, may be arranged at least partially directly on at least one power substrate 630, may be arranged completely on at least one power substrate 630, may be arranged completely directly on at least one power substrate 630, and/or the like.

Additionally, the encapsulation material 804 may extend from the at least one power substrate 630 up to the membrane structure 802. In aspects, the encapsulation material 804 may extend from the at least one power substrate 630 up to the membrane structure 802, into the membrane structure 802, through the membrane structure 802, above the membrane structure 802, and/or the like.

Further, the encapsulation material 804 may extend from the at least one power substrate 630 up to the aperture portions 806. In aspects, the encapsulation material 804 may extend from the at least one power substrate 630 up to the aperture portions 806, into the aperture portions 806, through the aperture portions 806, above the aperture portions 806, and/or the like.

In aspects, the encapsulation material 804 may be arranged at least partially on the signal connections 626, may be arranged at least partially directly on the signal connections 626, may be arranged completely on the signal connections 626, may be arranged completely directly on the signal connections 626, and/or the like.

The encapsulation material 804 may be any material that has a high dielectric strength, a low moisture absorption rate and can stably and/or continuously operate at high temperature commensurate with operation of the power module 100. In aspects, the encapsulation material 804 may be any material that can be used as a fill material for implementations of the power module 100 as described herein.

In aspects, the encapsulation material 804 may be an epoxy material, an epoxy encapsulation material, a silicone material, a silicone gel material, silicone gel encapsulation material, and/or like materials. In aspects, the encapsulation material 804 may be an epoxy material and/or an epoxy encapsulation material, and/or the like. A typical epoxy is a two part material containing a resin and a hardener. The resin can be any thermosetting resin family that includes phenol resin, melanin resin, epoxy resin, and/or the like. Additionally, the hardener can be any acid anhydride (thermal cure), aliphatic amine and polyamide (room temperature cure), aromatic amin (mid temperature cure, for example cure at 80˜150 degrees C.), and/or the like. The epoxy can be doped with and/or include metal fillers, silica infused fillers, and/or the like fillers to increase a mechanical strength, high heat resistance, improve workability of the material, such as a viscosity of the material, and/or the like.

In aspects, implementation of the encapsulation material 804 may be an epoxy material and/or epoxy encapsulation; and implementation of the composite physical containment structure 800 with the encapsulation material 804 and the membrane structure 802 may have the potential to increase power cycling life of the power module 100 and make the power module 100 more robust. Further, implementation of the composite physical containment structure 800 with the encapsulation material 804 and the membrane structure 802 may allow for implementation of a lidless case implementation of the power module 100.

The implementation of the composite physical containment structure 800 with the encapsulation material 804 as an epoxy material and/or epoxy encapsulation may also suppress moisture ingress, which allows the power module 100 to pass the moisture reliability tests such as Temperature Humidity Bias (THB) tests, Biased Highly Accelerated Stress Tests (BHAST), High Humidity, High Temperature Reverse Bias (H3TRB) tests, HV-H3TRB, THB-60, and/or the like. In this regard, reducing moisture ingress may reduce a rate of Ag dendrite growth.

However, the hardness and brittleness of the epoxy encapsulation material and bulk-inter epoxy bonds of the encapsulation material 804 may exert stress on the power devices 302 causing die crack, wire bond heel break of the power wire bonds 628, and/or the like during thermal shock. To mitigate this issue, the composite physical containment structure 800 implements the membrane structure 802 inside the power module 100 to reduce stress-strain on the power devices 302, other components of the power module 100, internal interfaces of the power module 100, and/or the like by implementing the encapsulation geometry of the composite physical containment structure 800 together with the membrane structure 802 and the encapsulation material 804 to reduce stress and reinforce the encapsulation matrix of the power module 100.

Implementation of the membrane structure 802 can be part of a housing body of the power module 100 or can be standalone. For example, the membrane structure 802 may be dropped in during power module build. The design of the membrane structure 802 can be optimized per case module design.

Additionally, the aperture portions 806 of the membrane structure 802 may be configured as strain reduction features. In this regard, a shape of the aperture portions 806 can be multi-sided and is not limited to a square or a rectangle as shown. For example, the aperture portions 806 may have Hexagon shape, a pentagon shape, a circle shape, an oval shape, a polygonal shape, a free-form curved shape, and/or the like. Further, a size and arrangement of the aperture portions 806 may be uniform, nonuniform, symmetrical, asymmetrical, and/or like.

The membrane structure 802 may include one or more non-conductive and HT (high temperature) stable materials, such as but not limited to plastic for the construction of the membrane, a rubber structure, a silicone structure, a silicone rubber structure, a thick rubber structure, a thick silicone structure, a thick silicone rubber structure, any material which is non-electrically conductive and can withstand temperatures in the 200 degree C. range, such as plastic, silicone rubber, composites, glass fiber, and/or the like. A size and arrangement of the membrane structure 802 may be dependent on a power, voltage, and/or current application of the power module 100. Further, a size and arrangement of the membrane structure 802 may be dependent on a size of the power module 100, a number of the power devices 302, and/or the like. In aspects, the membrane structure 802 may have fillets, sharp corners, any shape, and/or the like.

Likewise, a size and arrangement of the aperture portions 806 may be dependent on a power, voltage, and/or current application of the power module 100. Further, a size and arrangement of the aperture portions 806 may be dependent on a size of the power module 100, a number of the power devices 302, and/or the like.

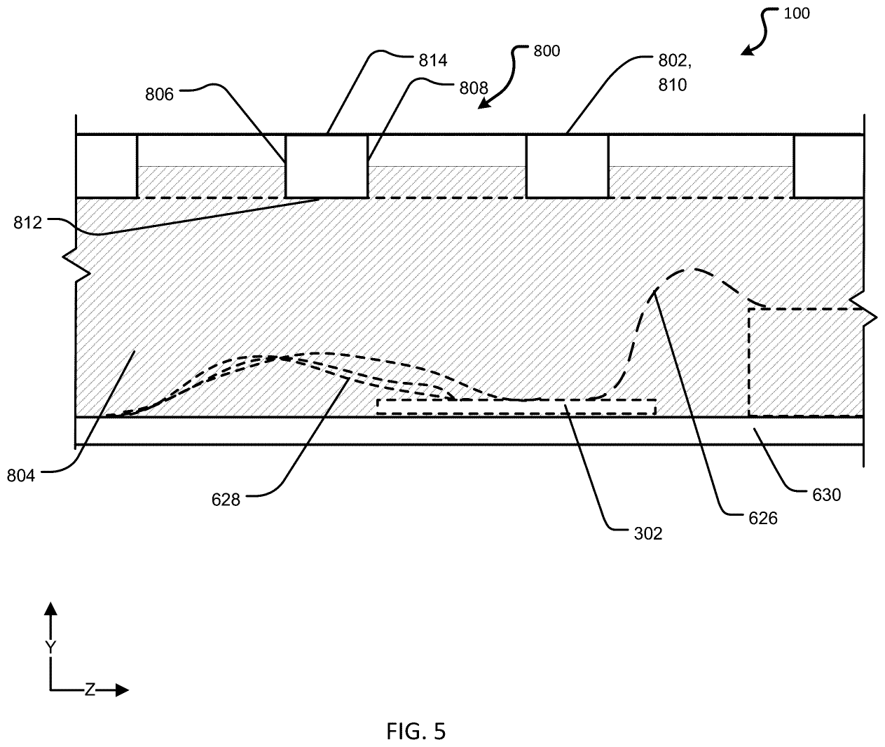

FIG. 5 illustrates a partial cross-section of the power module according to FIG. 1.

In particular, FIG. 5 illustrates further details of the membrane structure 802 and the encapsulation material 804. In this regard, the membrane structure 802 may include an upper surface 814, a lower surface 812, and aperture surfaces 808. The aperture surfaces 808 may define a shape and perimeter of the aperture portions 806. Further, the aperture surfaces 808 may extend between the upper surface 814 and the lower surface 812. The aperture surfaces 808 may extend vertically along the y-axis of the power module 100. In particular, the aperture surfaces 808 may be perpendicular or perpendicular to a surface of the at least one power substrate 630, the upper surface 814, and/or the lower surface 812. In this regard, generally perpendicular being within 0°-10°.

The upper surface 814 and the lower surface 812 may extend laterally along the z-axis of the power module 100. In particular, the upper surface 814 and the lower surface 812 may be parallel or generally parallel to a surface of the at least one power substrate 630. In this regard, generally parallel being within 0°-10°.

As further illustrated in FIG. 5, the encapsulation material 804 may extend from the power devices 302, the signal connections 626, and/or the power wire bonds 628 up to the membrane structure 802. In aspects, the encapsulation material 804 may extend from the power devices 302, the signal connections 626, and/or the power wire bonds 628 up to the lower surface 812, up to the aperture surfaces 808, up to the upper surface 814 and/or the like. As illustrated in FIG. 5, the encapsulation material 804 extends from the power devices 302, the signal connections 626, and/or the power wire bonds 628 up to the lower surface 812 and up to the aperture surfaces 808.

As further illustrated in FIG. 5, the encapsulation material 804 is illustrated as being arranged on at least one power substrate 630, the power wire bonds 628, and the power devices 302. However, the encapsulation material 804 may have other configurations as described herein.

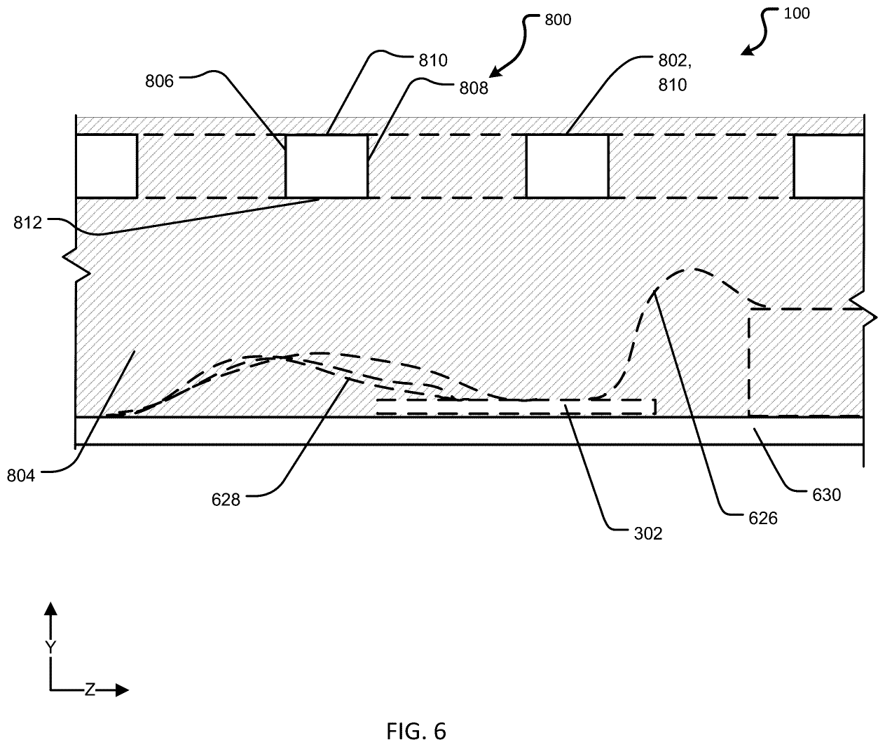

FIG. 6 illustrates a partial cross-section of the power module according to FIG. 1.

In particular, FIG. 6 illustrates another implementation of the membrane structure 802 and the encapsulation material 804. As further illustrated in FIG. 6, the encapsulation material 804 may extend from the power devices 302, the signal connections 626, and/or the power wire bonds 628 up to the membrane structure 802. As illustrated in FIG. 6, the encapsulation material 804 extends from the power devices 302, the signal connections 626, and/or the power wire bonds 628 up to the lower surface 812, up to the aperture surfaces 808, and up to the upper surface 814. In this regard, the encapsulation material 804 may encapsulate the power devices 302, the power wire bonds 628, the lower surface 812, the aperture surfaces 808, and/or the upper surface 814.

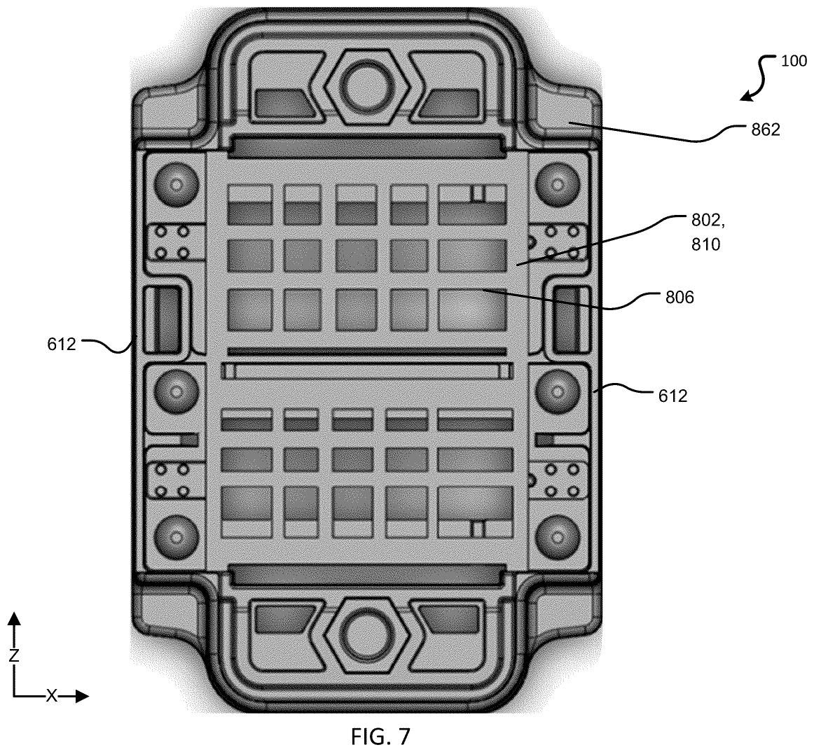

FIG. 7 illustrates a partial top view of a power module according to FIG. 1.

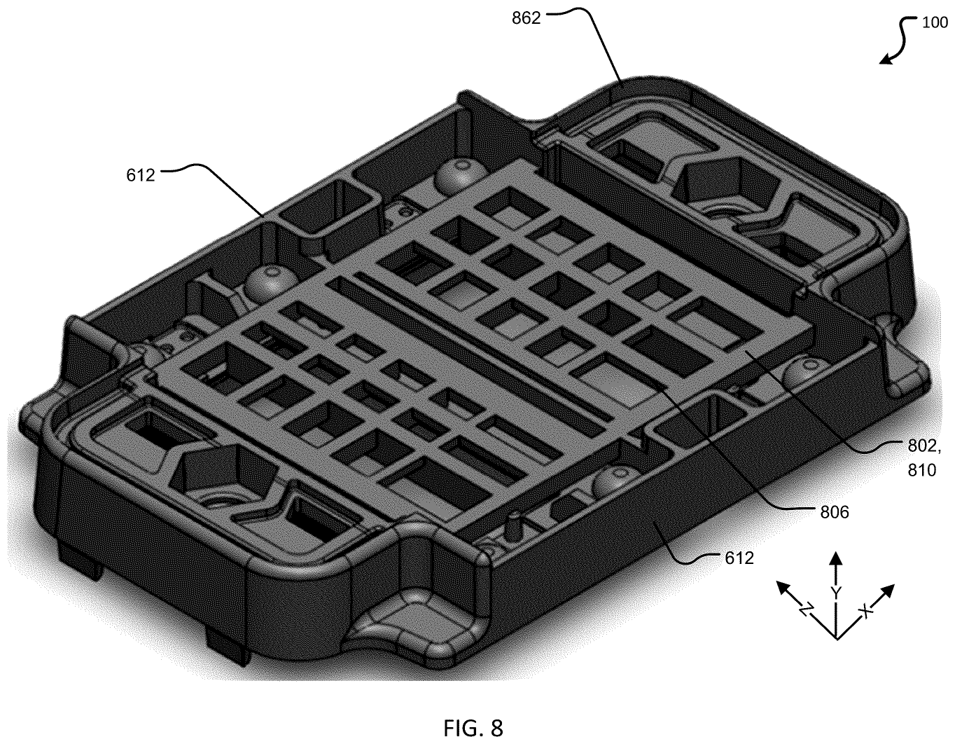

FIG. 8 illustrates a partial perspective cross-section view of the power module according to FIG. 1.

FIG. 7 and FIG. 8 illustrate the arrangement of the membrane structure 802 within a housing 862 of the power module 100. It is further noted that FIG. 7 and FIG. 8 illustrates the power module 100 without a number of components for ease of illustration and understanding.

In particular, in aspects the membrane structure 802 may be a separate structure from the housing of the power module 100. In other aspects, the membrane structure 802 may be structurally part of the housing of the power module 100. In aspects, the membrane structure 802 is arranged between the housing sidewalls 612; and during manufacture of the power module 100 may be inserted into the power module 100 between the housing sidewalls 612.

The housing 862 may be formed of a synthetic material. In one aspect, the housing 862 may be an injection molded plastic element. The housing 862 may provide electrical insulation, voltage creepage and clearance, structural support, and cavities for holding a voltage and moisture blocking encapsulation. In one aspect, the housing 862 may be formed in an injection molding process with reinforced high temperature plastic.

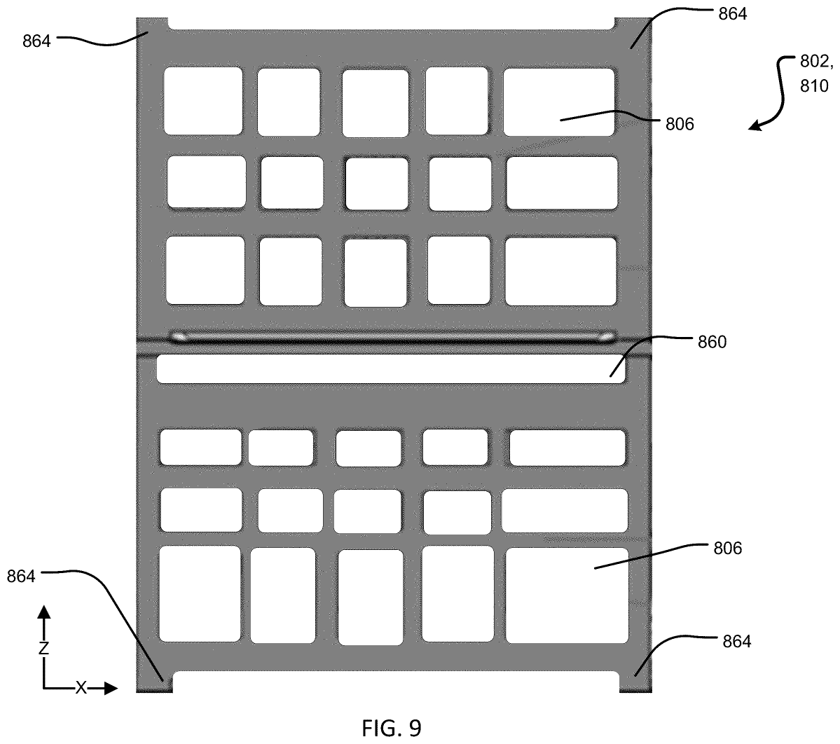

FIG. 9 illustrates a top view of the membrane structure according to aspects of the disclosure.

In particular, FIG. 9 illustrates a partial top view of the membrane structure 802 according to aspects of the disclosure. In this regard, the membrane structure 802 may include a slot 860 configured to allow the power contact 614 to extend through the membrane structure 802.

Additionally, the membrane structure 802 may include support tabs 864. In this regard, the support tabs 864 may be configured to be supported by a corresponding structure in the housing 862 of the power module 100. Alternatively and/or additionally, the membrane structure 802 may include support legs extending from the lower surface 812 of the membrane structure 802. The support legs may be configured to support the membrane structure 802 in the housing 862 of the power module 100.

The membrane structure 802 may be formed of a synthetic material. In one aspect, the membrane structure 802 may be an injection molded plastic element. In one aspect, the membrane structure 802 may be formed in an injection molding process with reinforced high temperature plastic.

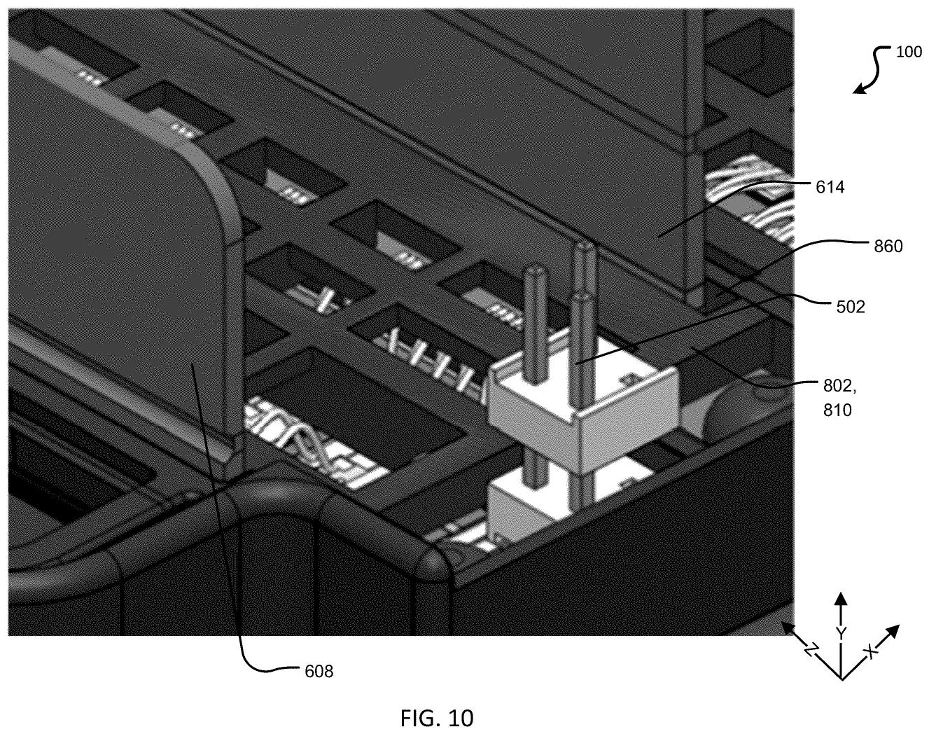

FIG. 10 illustrates a partial perspective view of the power module according to FIG. 1.

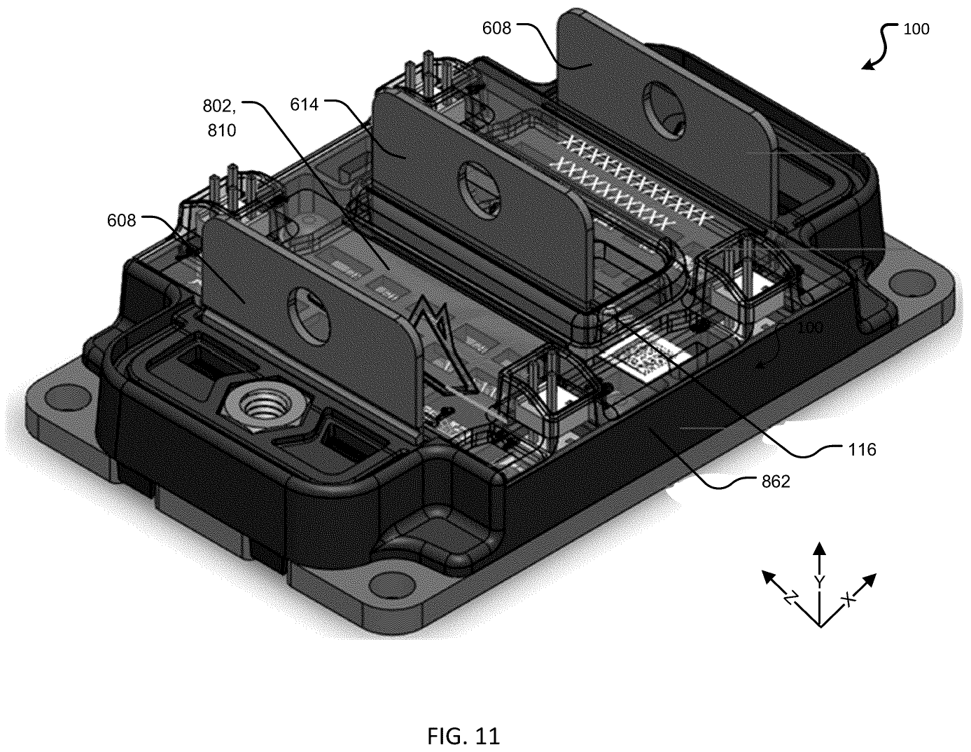

FIG. 11 illustrates a perspective view of the power module according to FIG. 1.

In particular, FIG. 10 illustrates details the arrangement of the power contact 614 with respect to the slot 860. FIG. 11 further illustrates that the power module 100 may further include the housing lid 116. The housing lid 116 may be a synthetic element. In one aspect, the housing lid 116 may be an injection molded plastic element. The housing lid 116 may provide electrical insulation, voltage creepage and clearance, and structural support. In this regard, the housing lid 116 together with the housing sidewalls 612 may form a closed assembly. The closed assembly may prevent the ingress of foreign materials from entering the interior of the power module 100. In one aspect, the housing lid 116 may be formed in an injection molding process with reinforced high temperature plastic.

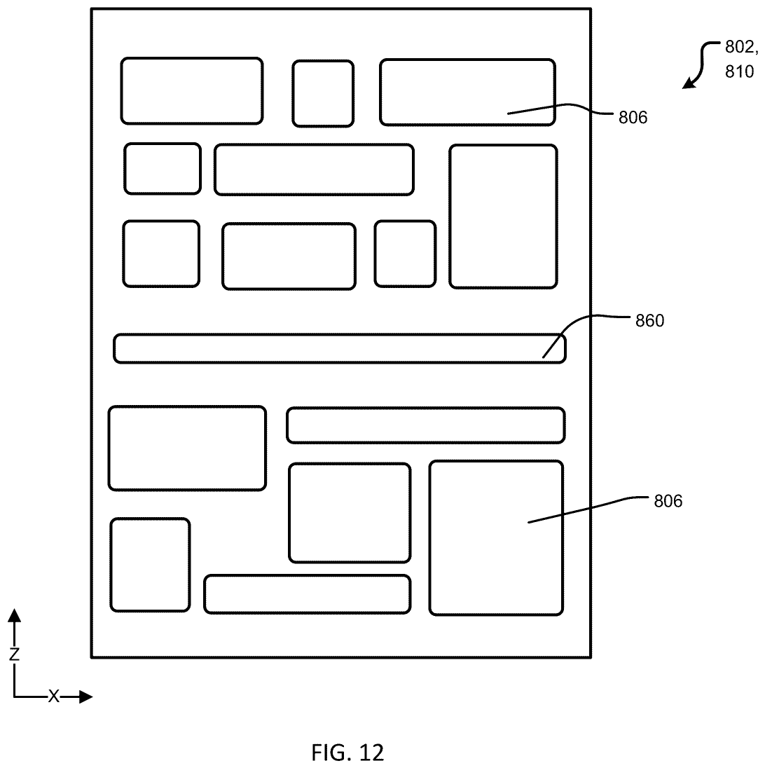

FIG. 12 illustrates a top view of another implementation of the membrane structure according to aspects of the disclosure.

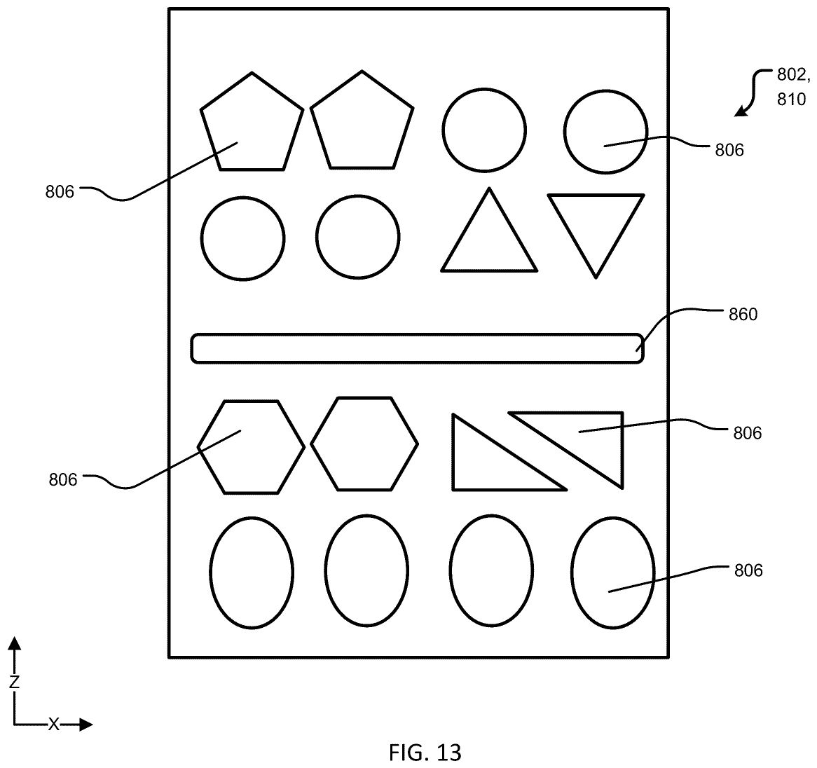

FIG. 13 illustrates a top view of another implementation of the membrane structure according to aspects of the disclosure.

In this regard, FIG. 12 illustrates that the membrane structure 802 may include any arrangement of the aperture portions 806 that may be uniform, nonuniform, symmetrical, asymmetrical, and/or like.

FIG. 13 illustrates that the membrane structure 802 may include any configuration of the aperture portions 806 and the aperture portions 806 may be configured with one or more various shapes that may include, but are not limited to, a Hexagon shape, a pentagon shape, a circle shape, an oval shape, a polygonal shape, a triangle shape, and/or the like. In aspects, the aperture portions 806 may be configured to have one or more implementations having a same shape; and/or the aperture portions 806 may be configured to have one or more implementations having a different shape. Further, a size and arrangement of the aperture portions 806 may be uniform, nonuniform, symmetrical, asymmetrical, and/or like.

In aspects, the power module 100 may include the at least one power substrate 630. The power module 100 also may include the power devices 302 on at least one power substrate 630. The power module 100 furthermore may include the power contacts 608. The power module 100 in addition may include the power wire bonds 628. The power module 100 moreover may include a housing having at least the housing sidewalls 612. The power module 100 also may include a composite physical containment structure 800 having the membrane structure 802; and the encapsulation material 804. The power module 100 furthermore may include where the encapsulation material 804 is arranged within the housing sidewalls 612.

The power module 100 may include the membrane structure 802 and the housing sidewalls 612 configured and structured with a same material. The power module 100 further may include the encapsulation material 804 arranged within the housing sidewalls 612. The power module 100 in addition may include the membrane structure 802 and the encapsulation material 804 having different materials having different material properties.

The power module 100 moreover may include where the membrane structure 802 is arranged between at least two of the power contacts 608. The power module 100 also may include where the encapsulation material 804 is arranged at least partially on the power devices 302 and/or the power wire bonds 628. The power module 100 further may include where the encapsulation material 804 extends from the power devices 302 and/or the power wire bonds 628 up to the membrane structure 802. The power module 100 in addition may include where the encapsulation material 804 extends from the power devices 302 into the membrane structure 802, through the membrane structure 802, and/or above the membrane structure 802. The power module 100 moreover may include where the encapsulation material 804 extends from the power devices 302 into the membrane structure 802 and above the membrane structure 802. The power module 100 also may include where the encapsulation material 804 may include an epoxy material. The power module 100 further may include where the membrane structure 802 occupies 20% 50% of a volume within the power module 100 with respect to a volume of the encapsulation material 804 within the power module 100. The power module 100 in addition may include where the membrane structure 802 may include stress reduction features and/or strain reduction features. The power module 100 moreover may include where the membrane structure 802 may include aperture portions arranged therein. The power module 100 also may include where the aperture portions are configured as the stress reduction features and/or strain reduction features.

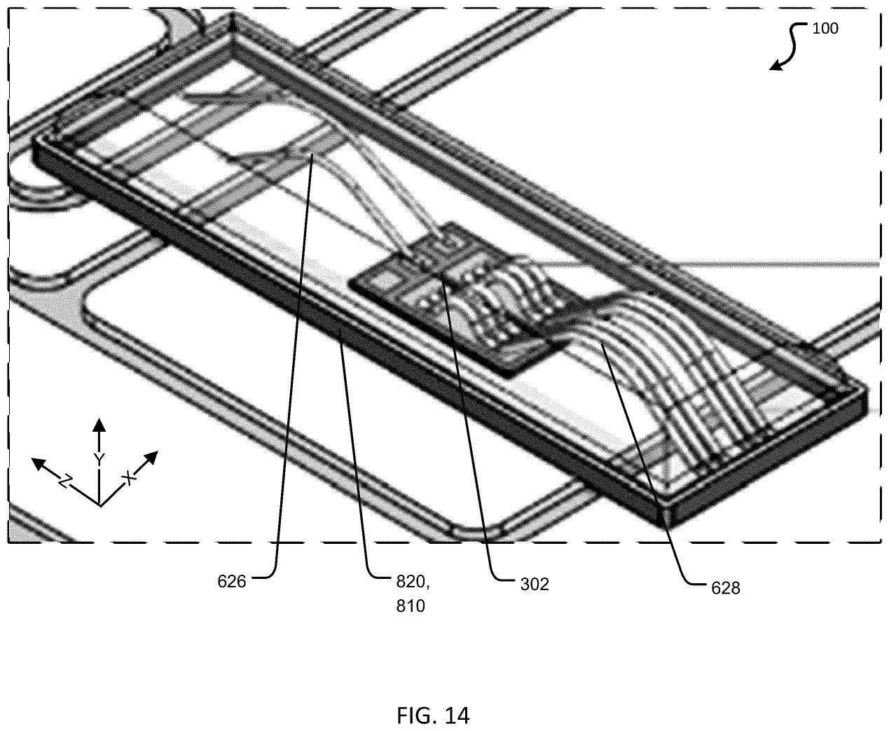

Additionally, the features of the power module 100 illustrated in FIGS. 1-13 and described herein may optionally be included in any other aspects of the power module 100 described with reference to FIGS. 14-23. Moreover, the features of the power module 100 illustrated in FIGS. 14-23 and described herein may optionally be included in any other aspects of the power module 100 described with reference to FIGS. 1-13.

FIG. 14 illustrates a partial perspective view of another implementation of the composite physical containment structure of the power module according to aspects of the disclosure.

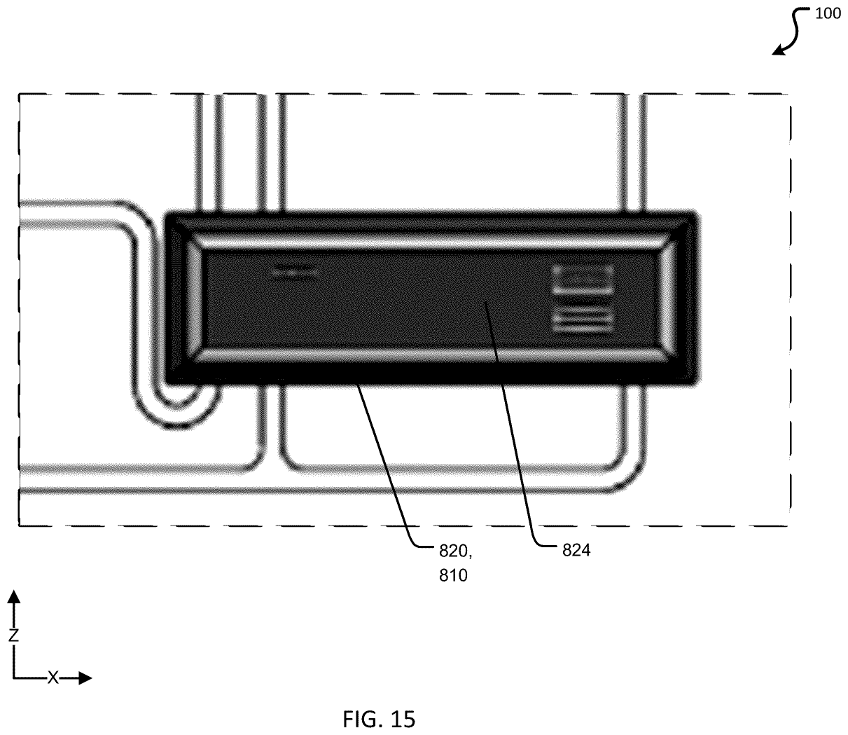

FIG. 15 illustrates a top view of the composite physical containment structure according to FIG. 14.

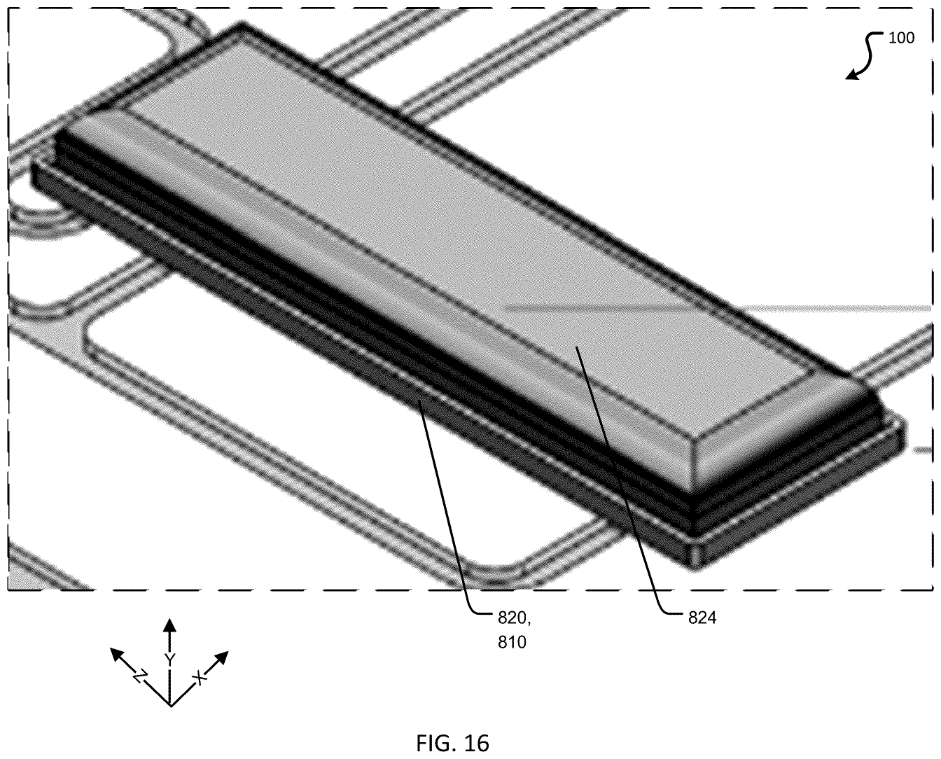

FIG. 16 illustrates another perspective view of the composite physical containment structure according to FIG. 14.

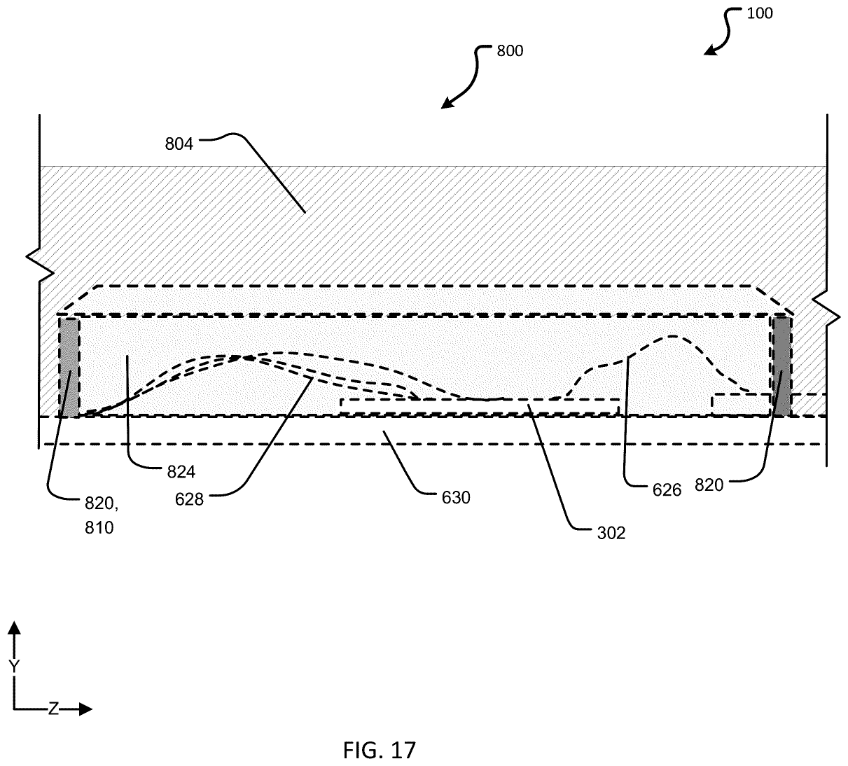

FIG. 17 illustrates a cross-sectional view of the composite physical containment structure according to FIG. 14.

In particular, FIG. 14 illustrates an implementation of the composite physical containment structure 800 having another implementation of the composite element 810. In aspects, the composite element 810 may be configured as a dam and fill structure that includes a dam structure 820. In this regard, as illustrated in FIG. 14, the composite physical containment structure 800 includes the dam structure 820, but FIG. 14 shows a configuration of the composite physical containment structure 800 prior to the addition of the encapsulation material 804.

In aspects, the dam structure 820 may be configured and arranged with a high viscosity material used to create a dam, which is filled with a dam encapsulation material 824. In aspects, the dam encapsulation material 824 may include any one or more of the materials described with respect to the materials used for the encapsulation material 804.

In aspects, the dam structure 820 may be formed by a dispensed material arranged on at least one power substrate 630. In aspects, the dam structure 820 may be formed by RTV silicone (room-temperature-vulcanizing silicone), a silicone epoxy composition, and/or the like. In aspects, the dam structure 820 may be formed by a material dispensed by a dispensing device.

In aspects, the dam structure 820 may be filled with the dam encapsulation material 824 that may include an epoxy material. However, the dam encapsulation material 824 within the dam structure 820 may utilize any of the various materials for the encapsulation material 804 as described herein.

In aspects, the rest of the power module 100 may be filled with the encapsulation material 804, that may include silicone. However, the another implementation of the encapsulation material 804 may utilize any of the various materials for the encapsulation material 804 as described herein. Accordingly, the dam encapsulation material 824 within the dam structure 820 may be a different material than the encapsulation material 804 outside and/or on the dam structure 820. Alternatively, the dam encapsulation material 824 within the dam structure 820 may be the same material as the encapsulation material 804 outside and/or on the dam structure 820.

In this case, the intent may be to protect the power devices 302 from moisture ingress and support the power wire bonds 628 and/or the signal connections 626 to enhance PC (power cycling) lifetime of the power module 100 and at the same time filling a bulk of the power module 100 with silicone gel implementation of the encapsulation material 804 outside the dam structure 820 and limiting the epoxy volume fill of the encapsulation material 804 within the dam structure 820 to minimize the stress-strain on the power devices 302.

The dam structure 820 may be arranged on at least one power substrate 630 and the dam structure 820 may surround at least partially one or more implementations of the power devices 302, one or more implementations of the signal connections 626, one or more implementations of the power wire bonds 628, and/or the like. In aspects, the dam structure 820 may completely surround one or more implementations of the power devices 302, one or more implementations of the signal connections 626, and/or one or more implementations of the power wire bonds 628.

In aspects, the dam structure 820 may extend along the x-axis and the z-axis parallel to a surface of the at least one power substrate 630. In aspects, the dam structure 820 may extend laterally and longitudinally parallel to a surface of the at least one power substrate 630. Further, the dam structure 820 may extend up from a surface of the at least one power substrate 630 vertically along the y-axis.

Additionally, the dam structure 820 may form a barrier for subsequent containment of the encapsulation material 804. In this regard, the dam structure 820 may prevent flow of the encapsulation material 804 prior to solidification outside of the boundaries of the dam structure 820.

FIG. 15 and FIG. 16 illustrate the composite physical containment structure 800 implementing the dam structure 820 with the dam encapsulation material 824 arranged within the dam structure 820. In this regard, the dam encapsulation material 824 arranged within the dam structure 820 may be arranged at least partially on the power devices 302, may be arranged at least partially directly on the power devices 302, may be arranged completely on the power devices 302, may be arranged completely directly on the power devices 302, and/or the like.

Further, the dam encapsulation material 824 arranged within the dam structure 820 may be arranged at least partially on the power wire bonds 628, may be arranged at least partially directly on the power wire bonds 628, may be arranged completely on the power wire bonds 628, may be arranged completely directly on the power wire bonds 628, and/or the like. Additionally, the dam encapsulation material 824 arranged within the dam structure 820 may be arranged at least partially on the signal connections 626, may be arranged at least partially directly on the signal connections 626, may be arranged completely on the signal connections 626, may be arranged completely directly on the signal connections 626, and/or the like.

Additionally, in aspects the dam encapsulation material 824 arranged within the dam structure 820 may form a top surface that may be generally parallel to a surface of the at least one power substrate 630. In other aspects, a separate lid structure may be arranged on the dam encapsulation material 824 arranged within the dam structure 820.

Further, the encapsulation material 804 arranged outside the dam structure 820 may be arranged at least partially on the dam structure 820, may be arranged at least partially directly on the dam structure 820, may be arranged completely on the dam structure 820, may be arranged completely directly on the dam structure 820, and/or the like.

In aspects, the power module 100 may include the at least one power substrate 630. The power module 100 also may include the power devices 302 on at least one power substrate 630. The power module 100 furthermore may include the power contacts 608. The power module 100 in addition may include the power wire bonds 628. The power module 100 moreover may include a composite physical containment structure 800 having the dam structure 820 and the encapsulation material 804. The power module 100 also may include where the dam structure 820 is filled with the dam encapsulation material 824. The power module 100 furthermore may include where the dam encapsulation material 824 and the encapsulation material 804 may include different materials having different material properties.

The power module 100 in addition may include where the dam structure 820 is filled with the dam encapsulation material 824. The power module 100 moreover may include where the dam encapsulation material 824 and the dam structure 820 are configured as stress reduction features and/or strain reduction features. The power module 100 also may include where the dam encapsulation material 824 may include an epoxy material; and where the encapsulation material 804 may include a silicone material. The power module 100 further may include where the dam encapsulation material 824 and the encapsulation material 804 may include different materials having different material properties. The power module 100 in addition may include where the dam encapsulation material 824 may include an epoxy material. The power module 100 moreover may include where the encapsulation material 804 may include a silicone material. The power module 100 also may include where the dam encapsulation material 824 is arranged within the dam structure 820; and where the dam encapsulation material 824 is arranged at least partially on the power devices, the power wire bonds 628, and/or signal connections 626. The power module 100 further may include where the dam encapsulation material 824 and the encapsulation material 804 may include different materials having different material properties. The power module 100 in addition may include a housing having at least the housing sidewalls 612, where the encapsulation material 804 is arranged within the housing sidewalls 612. The power module 100 moreover may include where the dam structure 820 may include but is not limited to RTV silicone (room-temperature-vulcanizing silicone) and/or a silicone epoxy composition. The power module 100 also may include where the dam structure 820 is arranged around at least one of the power devices. The power module 100 further may include where the dam structure 820 is arranged on at least one power substrate 630; and where the dam structure 820 surrounds at least partially one or more implementations of the power devices, one or more implementations of signal connections 626, and/or one or more implementations of the power wire bonds 628. The power module 100 in addition may include where the dam structure 820 extends along a surface of the at least one power substrate 630; and where the dam structure 820 extends up from the surface of the at least one power substrate 630. The power module 100 moreover may include where the encapsulation material 804 is arranged at least partially on the dam structure 820.

In aspects, implementation of the encapsulation material 804 and the dam structure 820 may have the potential to increase power cycling life of the power module 100 and make the power module 100 more robust. Further, implementation of the composite physical containment structure 800 with the encapsulation material 804 and the dam structure 820 may allow for implementation of a lidless case implementation of the power module 100.

The implementation of the composite physical containment structure 800 with the encapsulation material 804 and the dam structure 820 allows the power module 100 to pass the moisture reliability tests such as Temperature Humidity Bias (THB) tests, Biased Highly Accelerated Stress Tests (BHAST), High Humidity, High Temperature Reverse Bias (H3TRB) tests, HV-H3TRB, THB-60, and/or the like. In this regard, reducing moisture ingress may reduce a rate of Ag dendrite growth.

Additionally, the features of the power module 100 illustrated in FIGS. 14-17 and described herein may optionally be included in any other aspects of the power module 100 described with reference to FIGS. 1-13 and 18-23. Moreover, the features of the power module 100 illustrated in FIGS. 1-13 and 18-23 and described herein may optionally be included in any other aspects of the power module 100 described with reference to FIGS. 14-17.

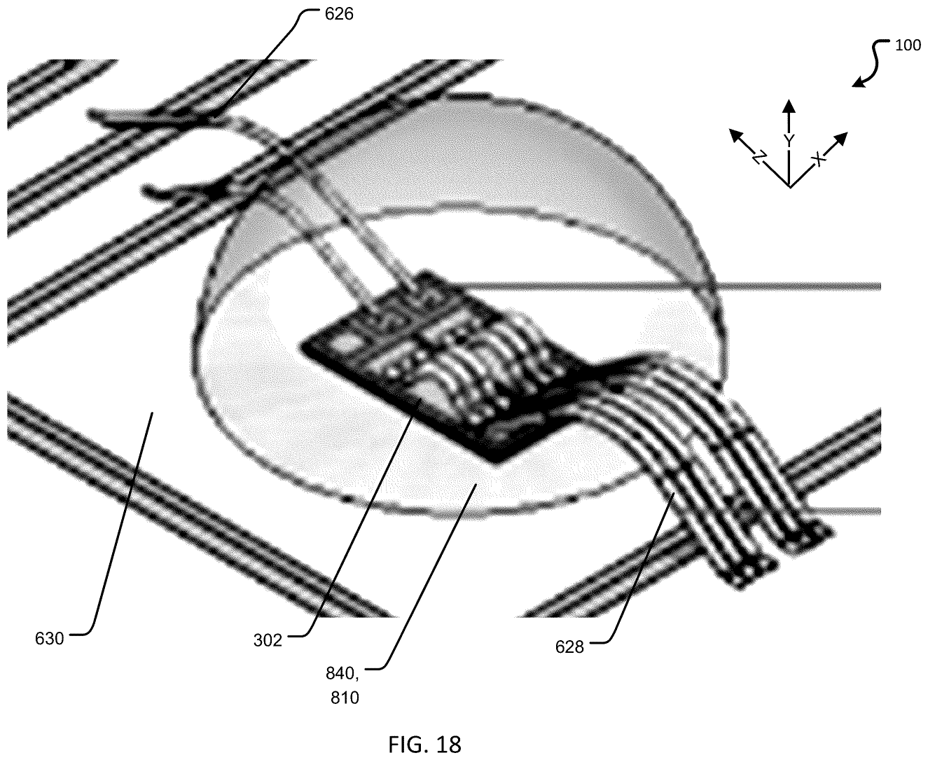

FIG. 18 illustrates a partial perspective view of another implementation of the composite physical containment structure of the power module according to aspects of the disclosure.

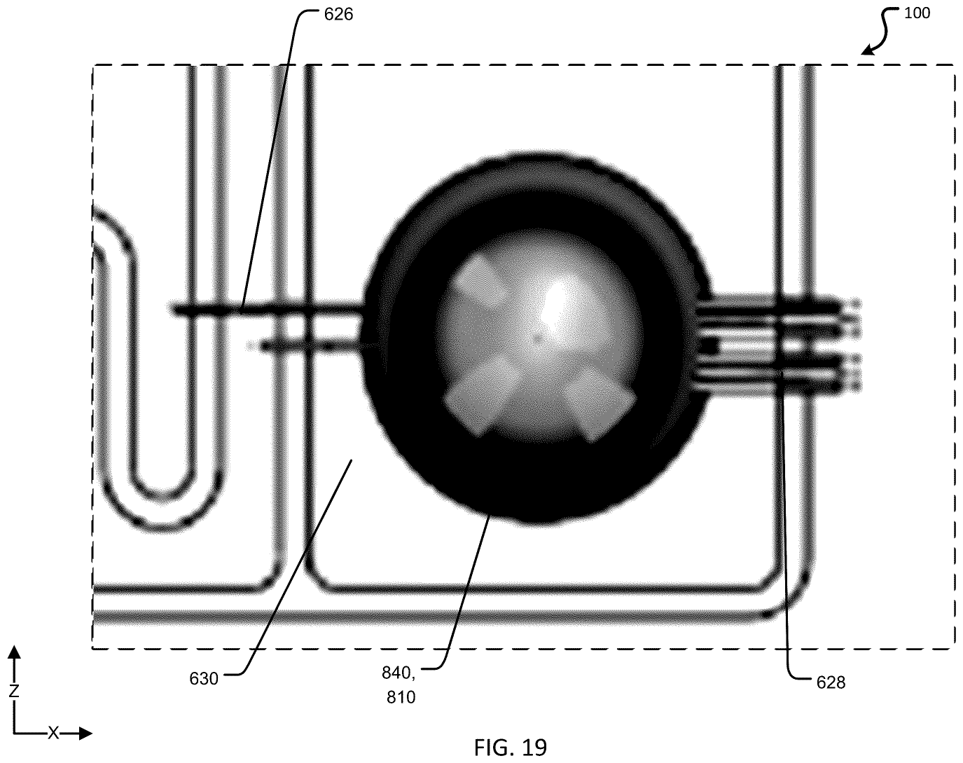

FIG. 19 illustrates a top view of the composite physical containment structure according to FIG. 18.

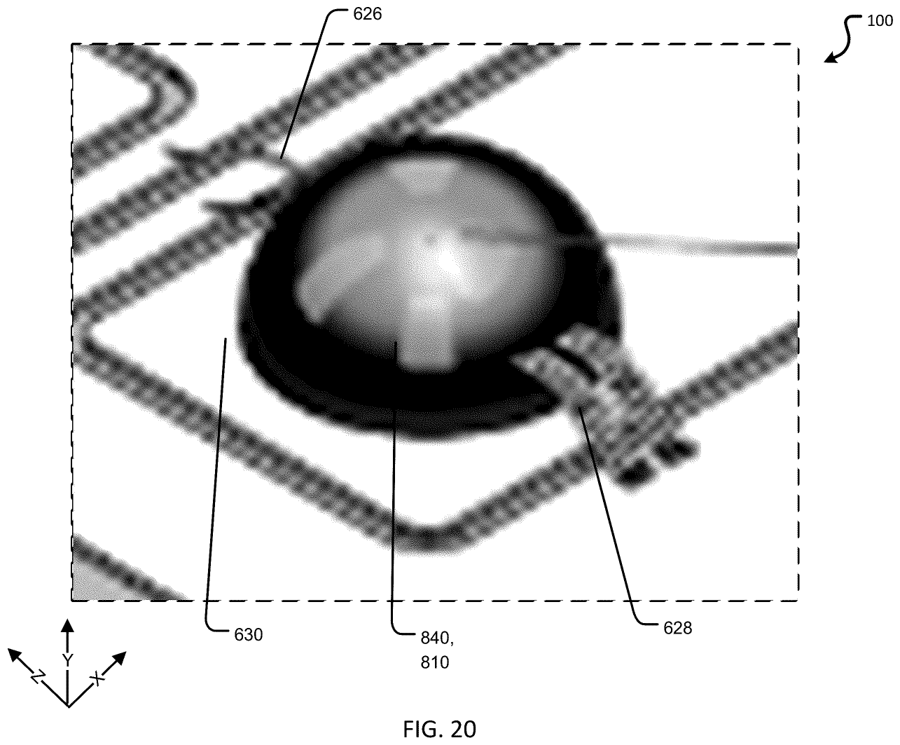

FIG. 20 illustrates another perspective view of the composite physical containment structure according to FIG. 18.

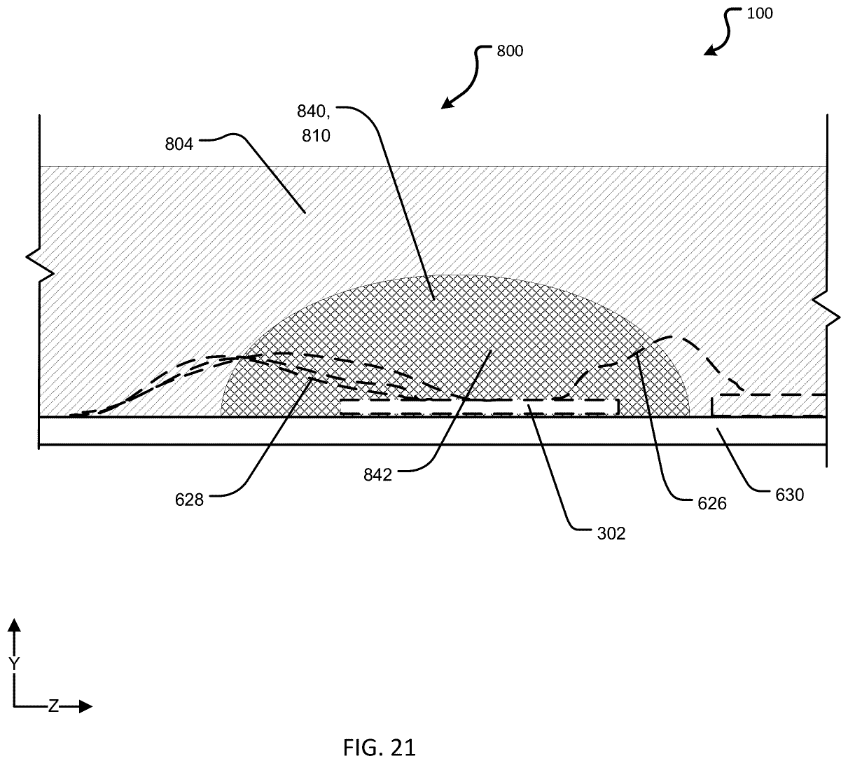

FIG. 21 illustrates a cross-sectional view of the composite physical containment structure according to FIG. 18.

In particular, FIG. 18 illustrates an implementation of the composite physical containment structure 800 having another implementation of the composite element 810. In aspects, the composite element 810 may be configured as a glob structure 840. In this regard, the glob structure 840 is shown as transparent for illustration and ease of understanding of the components of the power module 100. However, the glob structure 840 may be implemented as a non-transparent material as illustrated in FIG. 19 and FIG. 20.

In this regard, as illustrated in FIG. 18, the composite physical containment structure 800 may include the glob structure 840, but FIG. 18 shows a configuration of the composite physical containment structure 800 prior to the addition of the encapsulation material 804 over the glob structure 840.

In aspects, the glob structure 840 may be configured and arranged with a glob structure material 842. In aspects, the glob structure material 842 may be a high viscosity material. In particular aspects, the glob structure 840 may be configured and arranged with the glob structure material 842 having a material consistent with the encapsulation material 804 as described herein. In further aspects, the glob structure 840 may be configured and arranged using the glob structure material 842 implemented as an epoxy material as described herein.

In aspects, the rest of the power module 100 may be filled the encapsulation material 804, that may include silicone. However, the encapsulation material 804 may utilize any of the various materials for the encapsulation material 804 as described herein. Accordingly, the glob structure 840 may be a different material than the encapsulation material 804 outside the glob structure 840.

In this case, the intent is to protect the power devices 302 from moisture ingress and support the power wire bonds 628 to enhance PC (power cycling) lifetime of the power module 100 and at the same time filling a bulk of the power module 100 with the encapsulation material 804, such as a silicone gel implementation of the encapsulation material 804, outside the glob structure 840 and limiting the epoxy volume fill of the glob structure 840 to minimize the stress-strain on the power devices 302.

The glob structure 840 may be arranged on at least one power substrate 630 and the glob structure 840 may surround at least partially one or more implementations of the power devices 302, one or more implementations of the signal connections 626, and/or one or more implementations of the power wire bonds 628. In other aspects, the glob structure 840 may completely surround one or more implementations of the power devices 302, one or more implementations of the signal connections 626, and/or one or more implementations of the power wire bonds 628.

In aspects, the glob structure 840 may extend along the x-axis and the z-axis parallel to a surface of the at least one power substrate 630. In aspects, the glob structure 840 may extend laterally and longitudinally parallel to a surface of the at least one power substrate 630. Further, the glob structure 840 may extend up from a surface of the at least one power substrate 630 vertically along the y-axis.

FIG. 19 and FIG. 20 illustrate the composite physical containment structure 800 implementing the glob structure 840 with the encapsulation material 804 arranged within the glob structure 840. In this regard, the encapsulation material 804 arranged within glob structure 840 may be arranged at least partially on the power devices 302, may be arranged at least partially directly on the power devices 302, may be arranged completely on the power devices 302, may be arranged completely directly on the power devices 302, and/or the like. Further, the encapsulation material 804 arranged within glob structure 840 may be arranged at least partially on the power wire bonds 628, may be arranged at least partially directly on the power wire bonds 628, may be arranged completely on the power wire bonds 628, may be arranged completely directly on the power wire bonds 628, and/or the like. Additionally, the encapsulation material 804 arranged within glob structure 840 may be arranged at least partially on the signal connections 626, may be arranged at least partially directly on the signal connections 626, may be arranged completely on the signal connections 626, may be arranged completely directly on the signal connections 626, and/or the like.

As illustrated in FIG. 21, the encapsulation material 804 may be arranged outside the glob structure 840, may be arranged at least partially on the glob structure 840, may be arranged at least partially directly on the glob structure 840, may be arranged completely on the glob structure 840, may be arranged completely directly on the glob structure 840, and/or the like.

In aspects, implementation of the encapsulation material 804 and the glob structure 840 may have the potential to increase power cycling life of the power module 100 and make the power module 100 more robust. Further, implementation of the composite physical containment structure 800 with the encapsulation material 804 and the glob structure 840 may allow for implementation of a lidless case implementation of the power module 100.

The implementation of the composite physical containment structure 800 with the encapsulation material 804 and the glob structure 840 allows the power module 100 to pass the moisture reliability tests such as Temperature Humidity Bias (THB) tests, Biased Highly Accelerated Stress Tests (BHAST), High Humidity, High Temperature Reverse Bias (H3TRB) tests, HV-H3TRB, THB-60, and/or the like. In this regard, reducing moisture ingress may reduce a rate of Ag dendrite growth.

In aspects, the power module 100 may include the at least one power substrate 630. The power module 100 also may include the power devices 302 on at least one power substrate 630. The power module 100 furthermore may include the power contacts 608. The power module 100 in addition may include the power wire bonds 628. The power module 100 moreover may include a composite physical containment structure 800 having the glob structure 840 and the encapsulation material 804. The power module 100 also may include where the glob structure 840 and the encapsulation material 804 may include different materials having different material properties.

The power module 100 moreover may include where the glob structure 840 at least partially surrounds one or more implementations of the power devices, signal connections 626, and/or the power wire bonds 628. The power module 100 also may include where the glob structure 840 is configured as a stress reduction feature and/or strain reduction feature. The power module 100 further may include where the glob structure 840 extends along a surface of the at least one power substrate 630; and where the glob structure 840 extends up from a surface of the at least one power substrate 630. The power module 100 in addition may include where the encapsulation material 804 is arranged on the glob structure 840. The power module 100 moreover may include where the encapsulation material 804 is arranged at least partially on the glob structure 840. The power module 100 also may include where the glob structure 840 may include an epoxy material. The power module 100 further may include where the encapsulation material 804 is arranged at least partially on a surface of the at least one power substrate 630. The power module 100 in addition may include where the power devices 302 may include at least one power semiconductor device. The power module 100 moreover may include where the power devices 302 may include at least one power semiconductor device having a Metal Oxide Field Effect Transistor (MOSFET). The power module 100 also may include where the power devices 302 may include at least one power semiconductor device having a Silicon Carbide (SiC) Metal Oxide Field Effect Transistor (MOSFET). The power module 100 further may include where the encapsulation material 804 may include a silicone material. The power module 100 in addition may include where the power devices 302 may include at least one power semiconductor device configured as a power component.

In aspects, the power module 100 may include the at least one power substrate 630. The power module 100 also may include the power devices 302 on at least one power substrate 630. The power module 100 furthermore may include the power contacts 608. The power module 100 in addition may include the power wire bonds 628. The power module 100 moreover may include a composite physical containment structure 800 having the composite element 810 and the encapsulation material 804. The power module 100 also may include where the composite element 810 may include the membrane structure 802, the dam structure 820 and/or the glob structure 840. The power module 100 furthermore may include where a portion of the composite physical containment structure 800 is arranged at least partially on the power devices 302, the power wire bonds 628, and/or the at least one power substrate 630.

The power module 100 may include where the composite element 810 may include the membrane structure 802; and where the membrane structure 802 is arranged above the power devices 302 and the power wire bonds 628. The power module 100 also may include where the composite element 810 may include the glob structure 840. The power module 100 further may include where the glob structure 840 is arranged on at least one power substrate 630. The power module 100 further may include where the composite element 810 may include the dam structure 820.

Additionally, the features of the power module 100 illustrated in FIGS. 18-21 and described herein may optionally be included in any other aspects of the power module 100 described with reference to FIGS. 1-17. Moreover, the features of the power module 100 illustrated in FIGS. 1-17 and described herein may optionally be included in any other aspects of the power module 100 described with reference to FIGS. 18-21.

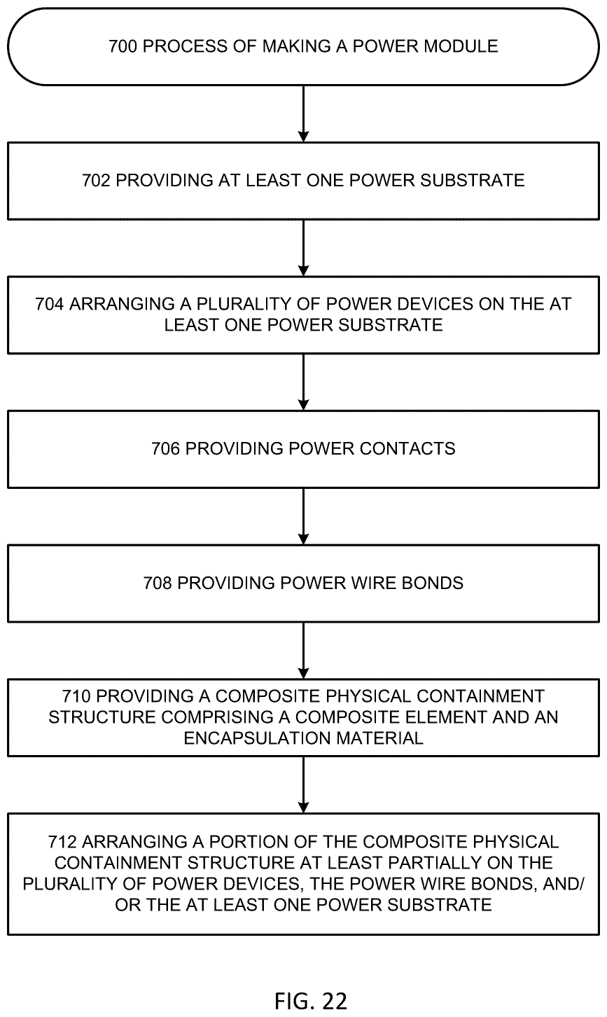

FIG. 22 shows an exemplary process of making a power module 700 according to the disclosure.

In particular, FIG. 22 shows an exemplary process of making a power module 700 according to the disclosure. In particular, it should be noted that the process of making a power module 700 is merely exemplary and may be modified consistent with the various aspects disclosed herein. Moreover, the process of making a power module 700 may be performed in a different order consistent with the aspects described above. Moreover, the process of making a power module 700 may be modified to have more or fewer process steps consistent with the various aspects disclosed herein.

The process of making a power module 700 of the disclosure may include providing at least one power substrate 702. In this regard, the providing at least one power substrate 702 may include any one or more materials, structures, arrangements, processes, and/or the like as described herein. Moreover, one or more proceeding or subsequent processes may also be implemented with respect to the providing at least one power substrate 702 consistent with the disclosure. In aspects, the providing at least one power substrate 702 may include providing the at least one power substrate 630 as disclosed herein.

The process of making a power module 700 of the disclosure may include arranging a plurality of power devices on at least one power substrate 704. In this regard, the arranging a plurality of power devices on at least one power substrate 704 may include any one or more materials, structures, arrangements, processes, and/or the like as described herein. Moreover, one or more proceeding or subsequent processes may also be implemented with respect to the arranging a plurality of power devices on at least one power substrate 704 consistent with the disclosure. In aspects, the arranging a plurality of power devices on at least one power substrate 704 may include arranging the power devices 302 on at least one power substrate 630 as disclosed herein.

The process of making a power module 700 of the disclosure may include providing power contacts 706. In this regard, the providing power contacts 706 may include any one or more materials, structures, arrangements, processes, and/or the like as described herein. Moreover, one or more proceeding or subsequent processes may also be implemented with respect to the providing power contacts 706 consistent with the disclosure. In aspects, the providing power contacts 706 may include providing the power contacts 608 as disclosed herein.

The process of making a power module 700 of the disclosure may include providing power wire bonds 708. In this regard, the providing power wire bonds 708 may include any one or more materials, structures, arrangements, processes, and/or the like as described herein. Moreover, one or more proceeding or subsequent processes may also be implemented with respect to the providing power wire bonds 708 consistent with the disclosure. In aspects, the providing power wire bonds 708 may include providing the power wire bonds 628 as disclosed herein.

The process of making a power module 700 of the disclosure may include providing a composite physical containment structure comprising a composite element and an encapsulation material 710. In this regard, the providing a composite physical containment structure comprising a composite element and an encapsulation material 710 may include any one or more materials, structures, arrangements, processes, and/or the like as described herein. Moreover, one or more proceeding or subsequent processes may also be implemented with respect to the providing a composite physical containment structure comprising a composite element and an encapsulation material 710 consistent with the disclosure.

In aspects, the providing a composite physical containment structure comprising a composite element and an encapsulation material 710 may include providing a composite physical containment structure having a composite element and the encapsulation material 804 as disclosed herein. In aspects, the providing a composite physical containment structure comprising a composite element and an encapsulation material 710 may include where the composite element may include the membrane structure 802, the dam structure 820 and/or the glob structure 840 as disclosed herein.

The process of making a power module 700 of the disclosure may include arranging a portion of the composite physical containment structure at least partially on the plurality of power devices, the power wire bonds, and/or the at least one power substrate 712. In this regard, the arranging a portion of the composite physical containment structure at least partially on the plurality of power devices, the power wire bonds, and/or the at least one power substrate 712 may include any one or more materials, structures, arrangements, processes, and/or the like as described herein. Moreover, one or more proceeding or subsequent processes may also be implemented with respect to the arranging a portion of the composite physical containment structure at least partially on the plurality of power devices, the power wire bonds, and/or the at least one power substrate 712 consistent with the disclosure.

In aspects, the arranging a portion of the composite physical containment structure at least partially on the plurality of power devices, the power wire bonds, and/or the at least one power substrate 712 may include dispensing the encapsulation material 804 with a dispensing device at least partially on the power devices and/or the power wire bonds 628. In aspects, the encapsulation material 804 may be injection molded, dispensed, and/or the like, and may be applied in the aperture portions 806, a groove in the housing sidewalls 612, and/or the like and compressed between the housing sidewalls 612 and the at least one power substrate 630.

In aspects, the arranging a portion of the composite physical containment structure at least partially on the plurality of power devices, the power wire bonds, and/or the at least one power substrate 712 may include dispensing a material with a dispensing device to form the dam structure 820. In aspects, the arranging a portion of the composite physical containment structure at least partially on the plurality of power devices, the power wire bonds, and/or the at least one power substrate 712 include dispensing with a dispensing device a dam encapsulation material 824 to fill the dam structure 820. The process further may include where the dam structure 820 may include but is not limited to RTV silicone (room-temperature-vulcanizing silicone) and/or a silicone epoxy composition.

In aspects, the dam structure 820 may be configured and arranged with a high viscosity material used to create a dam, which is filled with a dam encapsulation material 824. In aspects, the dam encapsulation material 824 may include any one or more of the materials described with respect to the materials used for the encapsulation material 804.

In aspects, the dam structure 820 may be filled with the dam encapsulation material 824 that may include an epoxy material. However, the dam encapsulation material 824 within the dam structure 820 may utilize any of the various materials for the encapsulation material 804 as described herein.

In aspects, the arranging a portion of the composite physical containment structure at least partially on the power devices 302, the power wire bonds, and/or the at least one power substrate 712 may include dispensing a material from a dispensing device to form the glob structure 840 on at least one power substrate 630. In aspects, the arranging a portion of the composite physical containment structure at least partially on the power devices 302, the power wire bonds, and/or the at least one power substrate 712 may include arranging the glob structure 840 to at least partially surround one or more implementations of the power devices 302, signal connections 626, and/or the power wire bonds 628.

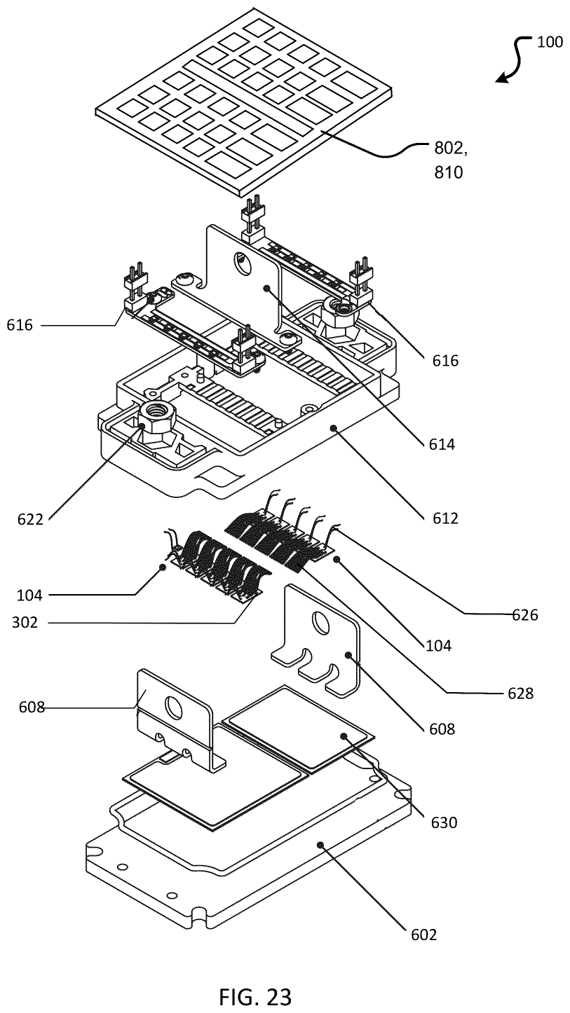

FIG. 23 illustrates a partial exploded perspective view of a power module according to aspects of the disclosure.

In particular, FIG. 23 illustrates exemplary implementation of the power module 100 implementing the composite element 810 with the membrane structure 802. However, the power module 100 of FIG. 23 may also alternatively and/or additionally implement the composite element 810 with the dam structure 820 (not shown in FIG. 23) and/or the composite element 810 with the glob structure 840 (not shown in FIG. 23). Additionally, the features of the power module 100 illustrated in FIG. 23 and described herein may optionally be included in any other aspects of the power module 100 described with reference to FIGS. 1-22. Moreover, the features of the power module 100 illustrated in FIGS. 1-22 and described herein may optionally be included in any other aspects of the power module 100 described with reference to FIG. 23.

In aspects, the power devices 302 of the power module 100 range in structure and purpose. The term ‘power device’ refers to various forms of transistors and diodes designed for high voltages and currents. The transistors may be controllable switches allowing for unidirectional or bidirectional current flow (depending on device type) while the diodes may allow for current flow in one direction and may not controllable. The transistor types may include but are not limited to Metal Oxide Field Effect Transistor (MOSFET), a Junction Field Effect Transistor (JFET), Bipolar Junction Transistor (BJT), Insulated Gate Bipolar Transistor (IGBT), and the like.

In aspects, the power devices 302 may include Wide Band Gap (WBG) semiconductors, including Gallium Nitride (GaN), Silicon Carbide (SiC), and the like, and offer numerous advantages over conventional Silicon (Si) as a material for the power devices 302. Nevertheless, various aspects of the disclosure may utilize Si type power devices and achieve a number of the benefits described herein.

In aspects, the power devices 302 of the power module 100 may have one or more switch positions 104. The power module 100 may implement the power contacts 608 and the power contact 614 as a first terminal, a second terminal, and a third terminal.

In one aspect, the base plate 602 may include a metal. In one aspect, the metal may include copper. Moreover, it is contemplated that the power module 100 may include fewer or different elements than those described herein.

In aspects, the power module 100 may include signal terminals 502. The specific pin-out of the signal terminals 502 may be modular and may be modified as necessary. As shown, there are four pairs of signal pins for the signal terminals 502 for differential signal transfer. Of course, any number of signal pins and any number of signal terminals may be implemented to provide the functionality as described in conjunction with the disclosure. Each switch position 104 may utilize a pair of pins with the signal terminals 502 for the gate signal and a source kelvin for optimal control. The other pin pairs of the signal terminals may be used for an internal temperature sensor, overcurrent sensing, or for other diagnostic signals. It is contemplated that more pins and/or more signal terminals may also be added to any of the rows if necessary, as long as they do not result in voltage isolation issues. In some aspects, the other diagnostic signals may be generated from diagnostic sensors that may include strain gauges sensing vibration, and the like. The diagnostic sensors can also determine humidity. Moreover, the diagnostic sensors may sense any environmental or device characteristic.

In one aspect, the base plate 602 may include a metal. In one aspect, the metal may include copper. Moreover, it is contemplated that the power module 100 may include fewer or different elements than those described herein.

In aspects, the base plate 602 may provide structural support to the power module 100 as well as facilitating heat spreading for thermal management of the power module 100. The base plate 602 may include a base metal, such as copper, aluminum, or the like, or a metal matrix composite (MMC) which may provide coefficient of thermal expansion (CTE) matching to reduce thermally generated stress. In one aspect, the MMC material may be a composite of a high conductivity metal such as copper, aluminum, and the like, and either a low CTE metal such as molybdenum, beryllium, tungsten, and/or a nonmetal such as diamond, silicon carbide, beryllium oxide, graphite, embedded pyrolytic graphite, or the like. Depending on the material, the base plate 602 may be formed by machining, casting, stamping, or the like. The base plate 602 may have a metal plating, such as nickel, silver, gold and/or the like, to protect surfaces of the base plate 602 and improve solder-ability. In one aspect, the base plate 602 may have a flat backside. In one aspect, the base plate 602 may have a convex profile to improve planarity after reflow. In one aspect, the base plate 602 may have pin fins for direct cooling.

In aspects, the at least one power substrate 630 may provide electrical interconnection, voltage isolation, heat transfer, and the like for the power devices 302. The at least one power substrate 630 may be constructed as a direct bond copper (DBC), an active metal braze (AMB), an insulated metal substrate (IMS), or the like. In the case of the IMS structure, the at least one power substrate 630 and the base plate 602 may be integrated as the same element. In some aspects, the at least one power substrate 630 may be attached to the base plate 602 with solder, thermally conductive epoxy, silver sintering or the like. In one aspect there may be two of the at least one power substrate 630, one for each switch position 104.

In aspects, a surface of one of the one or more power contacts 608 may form the V+ terminal or first terminal. A surface of one of the one or more power contacts 608 may form the phase terminal or third terminal. The one or more power contacts 608 may create a high current path between an external system and the at least one power substrate 630. The one or more power contacts 608 may be fabricated from sheet metal through an etching process, a stamping operation, or the like.

In aspects, the one or more power contacts 608 may have a partial thickness bend assist line to facilitate bending of the one or more power contacts 608 to aid in final assembly. In one aspect, the one or more power contacts 608 may be folded over the captive fastener 622. In one aspect, the one or more power contacts 608 may be soldered, ultrasonically welded, or the like directly to the at least one power substrate 630. The one or more power contacts 608 may have a metal plating, such as nickel, silver, gold, and/or the like to protect the surfaces and improve solder-ability.

In one aspect, a base of the power contact 608 may be split into feet to aid in the attach process. The base may have a metal plating, such as nickel, silver, and/or gold to protect the surfaces and improve solder-ability.

The power module 100 may further include one or more switch positions 104. The one or more switch positions 104 may include the power devices 302 that may include any combination of controllable switches and diodes placed in parallel to meet requirements for current, voltage, and efficiency. The power devices 302 may be attached with solder, conductive epoxy, a silver sintering material, or the like. The upper pads on the power devices 302, including the gate and the source, may be wire bonded to their respective locations with power wire bonds 628. The power wire bonds 628 may include aluminum, an aluminum alloy, copper, or the like wires, which may be ultrasonically welded, or the like at both feet, forming a conductive arch between two metal pads. Signal bonds may be formed in a similar manner and may be aluminum, gold, copper, or the like. In some aspects, the diameter of the wire of the power wire bonds at may be smaller than the wire of the power wire bonds 628.

The housing sidewalls 612 may be formed of a synthetic material. In one aspect, the housing sidewalls 612 may be an injection molded plastic element. The housing sidewalls 612 may provide electrical insulation, voltage creepage and clearance, structural support, and cavities for holding a voltage and moisture blocking encapsulation. In one aspect, the housing sidewalls 612 may be formed in an injection molding process with reinforced high temperature plastic.

A surface of the power contact 614 may form the V-terminal or second terminal. The power contact 614 may create a high current path between an external system and the power devices 302. The power contact 614 may be fabricated from sheet metal through an etching process, a stamping operation, or the like. The power contact 614 may be isolated from the at least one power substrate 630 by being embedded in the housing sidewalls 612 (as illustrated) or may be soldered or welded to a secondary power substrate as described below. The power contact 614 may include one or more apertures for receiving a corresponding fastener that fastens the power contact 614 to the housing sidewalls 612.

The low side switch position of the power devices 302 may be wire bonded directly from their terminals to the power contact 614. The power contact 614 may have a partial thickness bend assist line to aid in folding at the final assembly stage. The power contact 614 may have a metal plating, such as nickel, silver, gold, and/or the like to protect the surfaces and improve bond-ability.

The power module 100 may further include the signal interconnection assembly. The signal interconnection assembly may be a gate-source board. The signal interconnection assembly may be a small signal circuit board facilitating electrical connection from the signal contacts to the power devices 302. The signal interconnection assembly may allow for gate and source kelvin connection, as well as connection to additional nodes or internal sensing elements. The signal interconnection assembly may allow for individual gate resistors for each of the power devices 302. The signal interconnection assembly may be a printed circuit board, ceramic circuit board, flex circuit board, embedded metal strips, or the like arranged in the housing sidewalls 612. In one aspect, the signal interconnection assembly may include a plurality assemblies. In one aspect, the signal interconnection assembly 616 may include a plurality assemblies, one for each switch position 104.

In aspects, the captive fasteners 622 may be hex nuts placed in the housing sidewalls 612 and housing lid 116 and may be held captive underneath the power contacts 608 and the power contact 614 after they are folded over. Other types of fasteners or connectors are contemplated to implement the captive fasteners 622. The captive fasteners 622 may facilitate electrical connection to external buss bars or cables. The captive fasteners 622 may be arranged such that when the power module 100 is bolted to buss bars, the captive fasteners 622 and the power contacts 608 are pulled upwards into the bussing, forming a better quality electrical connection. If the captive fasteners 622 were affixed to the housing, they could act to pull the bussing down into the power module 100, which could form a poor connection due to the stiffness of the buss bars.

In one aspect, the housing sidewalls 612 may include an aperture having a shape consistent with the external shape of the captive fasteners 622 to prevent the captive fasteners 622 from rotating. A corresponding fastener may be received by the captive fasteners 622. The corresponding fastener extending through a fastener hole in the one or more power contacts 608 to facilitate electrical connection to external buss bars or cables.

The following are a number of nonlimiting EXAMPLES of aspects of the disclosure.

One EXAMPLE: a power module includes at least one power substrate. The power module also includes a plurality of power devices on at least one power substrate. The power module furthermore includes power contacts. The power module in addition includes power wire bonds. The power module moreover includes a composite physical containment structure having a composite element and an encapsulation material. The power module also includes where the composite element may include a membrane structure, a dam structure and/or a glob structure. The power module furthermore includes where a portion of the composite physical containment structure is arranged at least partially on the plurality of power devices, the power wire bonds, and/or the at least one power substrate.

The above-noted EXAMPLE may further include any one or a combination of more than one of the following EXAMPLES:

The power module includes where the composite element may include the membrane structure; and where the membrane structure is arranged above the power devices and the power wire bonds. The power module also includes may include a housing having at least housing sidewalls, where the membrane structure is arranged between the housing sidewalls. The power module further includes may include a housing having at least housing sidewalls, where the membrane structure and the housing sidewalls are configured and structured as a single component, such that the membrane structure is part of the housing sidewalls. The power module in addition includes may include a housing having at least housing sidewalls, where the membrane structure and the housing sidewalls are configured and structured as separate components. The power module moreover includes may include a housing having at least housing sidewalls, where the membrane structure and the housing sidewalls are configured and structured with a same material. The power module also includes may include a housing having at least housing sidewalls, where the membrane structure and the housing sidewalls are configured and structured with different materials having different material properties. The power module further includes may include a housing having at least housing sidewalls, where the encapsulation material is arranged within the housing sidewalls. The power module in addition includes where the membrane structure and the encapsulation material may include different materials having different material properties. The power module moreover includes where the membrane structure is arranged between at least two of the power contacts. The power module also includes where the encapsulation material is arranged at least partially on the power devices and/or the power wire bonds. The power module further includes where the encapsulation material extends from the power devices and/or the power wire bonds up to the membrane structure. The power module in addition includes where the encapsulation material extends from the power devices into the membrane structure, through the membrane structure, and/or above the membrane structure. The power module moreover includes where the encapsulation material extends from the power devices into the membrane structure and above the membrane structure. The power module also includes where the encapsulation material may include an epoxy material. The power module further includes where the membrane structure occupies 20% 50% of a volume within the power module with respect to a volume of the encapsulation material within the power module. The power module in addition includes where the membrane structure may include stress reduction features and/or strain reduction features. The power module moreover includes where the membrane structure may include aperture portions arranged therein. The power module also includes where the aperture portions are configured as stress reduction features and/or strain reduction features. The power module further includes where the encapsulation material extends from the power devices and/or the power wire bonds into the aperture portions, through the aperture portions, and/or above the aperture portions. The power module in addition includes where the encapsulation material extends from the power devices and/or the power wire bonds into the aperture portions and above the aperture portions. The power module moreover includes where the encapsulation material extends from the at least one power substrate up to the aperture portions. The power module also includes where the encapsulation material extends from the at least one power substrate up to the aperture portions and into the aperture portions. The power module further includes where the membrane structure may include an upper surface, a lower surface, and aperture surfaces; where the aperture surfaces define a shape and perimeter of the aperture portions; and where the aperture surfaces extend between the upper surface and the lower surface. The power module in addition includes where the encapsulation material extends from the power devices and/or the power wire bonds up to the lower surface of the membrane structure. The power module moreover includes where the encapsulation material extends from the power devices and/or the power wire bonds up to the aperture surfaces of the membrane structure. The power module also includes where the encapsulation material extends from the power devices and/or the power wire bonds up to the upper surface of the membrane structure. The power module further includes where the composite element may include the dam structure. The power module in addition includes where the dam structure is filled with a dam encapsulation material. The power module moreover includes where the dam encapsulation material and the dam structure are configured as stress reduction features and/or strain reduction features. The power module also includes where the dam encapsulation material may include an epoxy material; and where the encapsulation material may include a silicone material. The power module further includes where the dam encapsulation material and the encapsulation material may include different materials having different material properties. The power module in addition includes where the dam encapsulation material may include an epoxy material. The power module moreover includes where the encapsulation material may include a silicone material. The power module also includes where the dam encapsulation material is arranged within the dam structure; and where the dam encapsulation material is arranged at least partially on the power devices, the power wire bonds, and/or signal connections. The power module further includes where the dam encapsulation material and the encapsulation material may include different materials having different material properties. The power module in addition includes may include a housing having at least housing sidewalls, where the encapsulation material is arranged within the housing sidewalls. The power module moreover includes where the dam structure may include but is not limited to RTV silicone (room-temperature-vulcanizing silicone) and/or a silicone epoxy composition. The power module also includes where the dam structure is arranged around at least one of the power devices. The power module further includes where the dam structure is arranged on at least one power substrate; and where the dam structure surrounds at least partially one or more implementations of the power devices, one or more implementations of signal connections, and/or one or more implementations of the power wire bonds. The power module in addition includes where the dam structure extends along a surface of the at least one power substrate; and where the dam structure extends up from the surface of the at least one power substrate. The power module moreover includes where the encapsulation material is arranged at least partially on the dam structure. The power module also includes where the composite element may include the glob structure. The power module further includes where the glob structure is arranged on at least one power substrate. The power module in addition includes where the glob structure and the encapsulation material may include different materials having different material properties. The power module moreover includes where the glob structure at least partially surrounds one or more implementations of the power devices, signal connections, and/or the power wire bonds. The power module also includes where the glob structure is configured as a stress reduction feature and/or strain reduction feature. The power module further includes where the glob structure extends along a surface of the at least one power substrate; and where the glob structure extends up from a surface of the at least one power substrate. The power module in addition includes where the encapsulation material is arranged on the glob structure. The power module moreover includes where the encapsulation material is arranged at least partially on the glob structure. The power module also includes where the glob structure may include an epoxy material. The power module further includes where the encapsulation material is arranged at least partially on a surface of the at least one power substrate. The power module in addition includes where the plurality of power devices may include at least one power semiconductor device. The power module moreover includes where the plurality of power devices may include at least one power semiconductor device having a Metal Oxide Field Effect Transistor (MOSFET). The power module also includes where the plurality of power devices may include at least one power semiconductor device having a Silicon Carbide (SiC) Metal Oxide Field Effect Transistor (MOSFET). The power module further includes where the encapsulation material may include a silicone material. The power module in addition includes where the plurality of power devices may include at least one power semiconductor device configured as a power component.

One EXAMPLE: a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a composite element and an encapsulation material. The process also includes arranging a portion of the composite physical containment structure at least partially on the plurality of power devices, the power wire bonds, and/or the at least one power substrate. The process furthermore includes where the composite element may include a membrane structure, a dam structure and/or a glob structure.

The above-noted EXAMPLE may further include any one or a combination of more than one of the following EXAMPLES:

The process includes may include: configuring the composite element as the membrane structure; and arranging the membrane structure above the power devices and the power wire bonds. The process also includes may include: providing a housing having at least housing sidewalls; and arranging the membrane structure between the housing sidewalls. The process further includes may include: providing a housing having at least housing sidewalls; and configuring and structuring the membrane structure and the housing sidewalls as a single component, such that the membrane structure is part of the housing sidewalls. The process in addition includes may include: providing a housing having at least housing sidewalls; and configuring and structuring the membrane structure and the housing sidewalls as separate components. The process moreover includes may include: providing a housing having at least housing sidewalls; and configuring and structuring the membrane structure and the housing sidewalls with a same material. The process also includes may include: providing a housing having at least housing sidewalls; and configuring and structuring the membrane structure and the housing sidewalls are with different materials having different material properties. The process further includes may include: providing a housing having at least housing sidewalls; and arranging the encapsulation material within the housing sidewalls. The process in addition includes, may include configuring and structuring the membrane structure and the encapsulation material with different materials having different material properties. The process moreover includes may include arranging the membrane structure between at least two of the power contacts. The process also includes may include arranging the encapsulation material at least partially on the power devices and/or the power wire bonds. The process further includes may include dispensing the encapsulation material with a dispensing device at least partially on the power devices and/or the power wire bonds. The process in addition includes may include arranging the encapsulation material to extend from the power devices and/or the power wire bonds up to the membrane structure. The process moreover includes may include arranging the encapsulation material to extend from the power devices into the membrane structure, through the membrane structure, and/or above the membrane structure. The process also includes may include arranging the encapsulation material to extend from the power devices into the membrane structure and above the membrane structure. The process further includes where the encapsulation material may include an epoxy material. The process in addition includes may include arranging the membrane structure to occupy 20% 50% of a volume within the power module with respect to a volume of the encapsulation material within the power module. The process moreover includes may include configuring and structuring the membrane structure with stress reduction features and/or strain reduction features. The process also includes may include forming aperture portions in the membrane structure. The process further includes may include configuring and structuring the aperture portions as stress reduction features and/or strain reduction features. The process in addition includes may include arranging the encapsulation material to extend from the power devices and/or the power wire bonds into the aperture portions, through the aperture portions, and/or above the aperture portions. The process moreover includes may include arranging the encapsulation material to extend from the power devices and/or the power wire bonds into the aperture portions and above the aperture portions. The process also includes may include arranging the encapsulation material to extend from the at least one power substrate up to the aperture portions. The process further includes may include arranging the encapsulation material to extend from the at least one power substrate up to the aperture portions and into the aperture portions. The process in addition includes where the membrane structure may include an upper surface, a lower surface, and aperture surfaces; where the aperture surfaces define a shape and perimeter of the aperture portions; and where the aperture surfaces extend between the upper surface and the lower surface. The process moreover includes may include arranging the encapsulation material to extend from the power devices and/or the power wire bonds up to the lower surface of the membrane structure. The process also includes may include arranging the encapsulation material to extend from the power devices and/or the power wire bonds up to the aperture surfaces of the membrane structure. The process further includes may include arranging the encapsulation material to extend from the power devices and/or the power wire bonds up to the upper surface of the membrane structure. The process in addition includes may include configuring the composite element as the dam structure. The process moreover includes may include dispensing a material with a dispensing device to form the dam structure. The process also includes may include filling the dam structure with a dam encapsulation material. The process further includes where the dam encapsulation material may include an epoxy material; and where the encapsulation material may include a silicone material. The process in addition includes where the dam encapsulation material may include an epoxy material. The process moreover includes where the encapsulation material may include a silicone material. The process also includes may include: arranging the dam encapsulation material within the dam structure; and arranging the dam encapsulation material at least partially on the power devices, the power wire bonds, and/or signal connections. The process further includes may include configuring and structuring the dam encapsulation material and the dam structure as stress reduction features and/or strain reduction features. The process in addition includes may include configuring and structuring the dam encapsulation material and the encapsulation material with different materials having different material properties. The process moreover includes may include further: providing a housing having at least housing sidewalls; and configuring and structuring the encapsulation material within the housing sidewalls. The process also includes may include dispensing with a dispensing device a dam encapsulation material to fill the dam structure. The process further includes where the dam structure may include but is not limited to RTV silicone (room-temperature-vulcanizing silicone) and/or a silicone epoxy composition. The process in addition includes may include arranging the dam structure around at least one of the power devices. The process moreover includes may include: arranging the dam structure on at least one power substrate; and arranging the dam structure to surround at least partially one or more implementations of the power devices, one or more implementations of signal connections, and/or one or more implementations of the power wire bonds. The process also includes may include: arranging the dam structure to extend along a surface of the at least one power substrate; and arranging the dam structure to extend up from the surface of the at least one power substrate. The process further includes may include arranging the encapsulation material at least partially on the dam structure. The process in addition includes may include configuring the composite element to may include the glob structure. The process moreover includes may include arranging the glob structure on at least one power substrate. The process also includes may include dispensing a material from a dispensing device to form the glob structure on at least one power substrate. The process further includes may include arranging the glob structure to at least partially surround one or more implementations of the power devices, signal connections, and/or the power wire bonds. The process in addition includes may include: arranging the glob structure to extend along a surface of the at least one power substrate; and arranging the glob structure to extend up from a surface of the at least one power substrate. The process moreover includes may include arranging the encapsulation material on the glob structure. The process also includes may include dispensing the encapsulation material with a dispensing device at least partially on the glob structure. The process further includes where the glob structure may include an epoxy material. The process in addition includes may include arranging the encapsulation material at least partially on a surface of the at least one power substrate. The process moreover includes where the encapsulation material may include a silicone material. The process also includes may include configuring and structuring the glob structure and the encapsulation material with different materials having different material properties. The process further includes may include configuring and structuring the glob structure as a stress reduction feature and/or strain reduction feature. The process in addition includes where the plurality of power devices may include at least one power semiconductor device. The process moreover includes where the plurality of power devices may include at least one power semiconductor device having a Metal Oxide Field Effect Transistor (MOSFET). The process also includes where the plurality of power devices may include at least one power semiconductor device having a Silicon Carbide (SiC) Metal Oxide Field Effect Transistor (MOSFET). The process further includes where the plurality of power devices may include at least one power semiconductor device configured as a power component.

One EXAMPLE: a power module includes at least one power substrate. The power module also includes a plurality of power devices on at least one power substrate. The power module furthermore includes power contacts. The power module in addition includes power wire bonds. The power module moreover includes a housing having at least housing sidewalls. The power module also includes a composite physical containment structure having a membrane structure; and an encapsulation material. The power module furthermore includes where the encapsulation material is arranged within the housing sidewalls.

The above-noted EXAMPLE may further include any one or a combination of more than one of the following EXAMPLES:

The power module includes where the membrane structure is arranged above the power devices and the power wire bonds. The power module also includes may include a housing having at least housing sidewalls, where the membrane structure and the housing sidewalls are configured and structured as a single component, such that the membrane structure is part of the housing sidewalls. The power module further includes may include a housing having at least housing sidewalls, where the membrane structure and the housing sidewalls are configured and structured as separate components. The power module in addition includes may include a housing having at least housing sidewalls, where the membrane structure and the housing sidewalls are configured and structured with a same material. The power module moreover includes may include a housing having at least housing sidewalls, where the membrane structure and the housing sidewalls are configured and structured with different materials having different material properties. The power module also includes may include a housing having at least housing sidewalls, where the membrane structure is arranged between the housing sidewalls. The power module further includes where the membrane structure and the encapsulation material may include different materials having different material properties. The power module in addition includes where the membrane structure is arranged between at least two of the power contacts. The power module moreover includes where the encapsulation material is arranged at least partially on the power devices and/or the power wire bonds. The power module also includes where the encapsulation material extends from the power devices and/or the power wire bonds up to the membrane structure. The power module further includes where the encapsulation material extends from the power devices into the membrane structure, through the membrane structure, and/or above the membrane structure. The power module in addition includes where the encapsulation material extends from the power devices into the membrane structure and above the membrane structure. The power module moreover includes where the encapsulation material may include an epoxy material. The power module also includes where the membrane structure occupies 20% 50% of a volume within the power module with respect to a volume of the encapsulation material within the power module. The power module further includes where the membrane structure may include stress reduction features and/or strain reduction features. The power module in addition includes where the membrane structure may include aperture portions arranged therein. The power module moreover includes where the aperture portions are configured as stress reduction features and/or strain reduction features. The power module also includes where the encapsulation material extends from the power devices and/or the power wire bonds into the aperture portions, through the aperture portions, and/or above the aperture portions. The power module further includes where the encapsulation material extends from the power devices and/or the power wire bonds into the aperture portions and above the aperture portions. The power module in addition includes where the encapsulation material extends from the at least one power substrate up to the aperture portions. The power module moreover includes where the encapsulation material extends from the at least one power substrate up to the aperture portions and into the aperture portions. The power module also includes where the membrane structure may include an upper surface, a lower surface, and aperture surfaces; where the aperture surfaces define a shape and perimeter of the aperture portions; and where the aperture surfaces extend between the upper surface and the lower surface. The power module further includes where the encapsulation material extends from the power devices and/or the power wire bonds up to the lower surface of the membrane structure. The power module in addition includes where the encapsulation material extends from the power devices and/or the power wire bonds up to the aperture surfaces of the membrane structure. The power module moreover includes where the encapsulation material extends from the power devices and/or the power wire bonds up to the upper surface of the membrane structure.

One EXAMPLE: a power module includes at least one power substrate. The power module also includes a plurality of power devices on at least one power substrate. The power module furthermore includes power contacts. The power module in addition includes power wire bonds. The power module moreover includes a composite physical containment structure having a dam structure and an encapsulation material. The power module also includes where the dam structure is filled with a dam encapsulation material. The power module furthermore includes where the dam encapsulation material and the encapsulation material may include different materials having different material properties.

The above-noted EXAMPLE may further include any one or a combination of more than one of the following EXAMPLES:

The power module includes may include a housing having at least housing sidewalls, where the encapsulation material is arranged within the housing sidewalls. The power module also includes where the dam encapsulation material and the dam structure are configured as stress reduction features and/or strain reduction features. The power module further includes where the dam encapsulation material may include an epoxy material; and where the encapsulation material may include a silicone material. The power module in addition includes where the dam encapsulation material may include an epoxy material. The power module moreover includes where the encapsulation material may include a silicone material. The power module also includes where the dam encapsulation material is arranged within the dam structure; and where the dam encapsulation material is arranged at least partially on the power devices, the power wire bonds, and/or signal connections. The power module further includes where the dam structure may include but is not limited to RTV silicone (room-temperature-vulcanizing silicone) and/or a silicone epoxy composition. The power module in addition includes where the dam structure is arranged around at least one of the power devices. The power module moreover includes where the dam structure is arranged on at least one power substrate; and where the dam structure surrounds at least partially one or more implementations of the power devices, one or more implementations of signal connections, and/or one or more implementations of the power wire bonds. The power module also includes where the dam structure extends along a surface of the at least one power substrate; and where the dam structure extends up from the surface of the at least one power substrate. The power module further includes where the encapsulation material is arranged at least partially on the dam structure.

One EXAMPLE: a power module includes at least one power substrate. The power module also includes a plurality of power devices on at least one power substrate. The power module furthermore includes power contacts. The power module in addition includes power wire bonds. The power module moreover includes a composite physical containment structure having a glob structure and an encapsulation material. The power module also includes where the glob structure and the encapsulation material may include different materials having different material properties.

The above-noted EXAMPLE may further include any one or a combination of more than one of the following EXAMPLES:

The power module includes where the glob structure at least partially surrounds one or more implementations of the power devices, signal connections, and/or the power wire bonds. The power module also includes where the glob structure is configured as a stress reduction feature and/or strain reduction feature. The power module further includes where the glob structure extends along a surface of the at least one power substrate; and where the glob structure extends up from a surface of the at least one power substrate. The power module in addition includes where the encapsulation material is arranged on the glob structure. The power module moreover includes where the encapsulation material is arranged at least partially on the glob structure. The power module also includes where the glob structure may include an epoxy material. The power module further includes where the encapsulation material is arranged at least partially on a surface of the at least one power substrate. The power module in addition includes where the encapsulation material may include a silicone material. The power module moreover includes where the plurality of power devices may include at least one power semiconductor device. The power module also includes where the plurality of power devices may include at least one power semiconductor device having a Metal Oxide Field Effect Transistor (MOSFET). The power module further includes where the plurality of power devices may include at least one power semiconductor device having a Silicon Carbide (SiC) Metal Oxide Field Effect Transistor (MOSFET). The power module in addition includes where the plurality of power devices may include at least one power semiconductor device configured as a power component.

One EXAMPLE: a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a membrane structure and an encapsulation material. The process also includes providing a housing having at least housing sidewalls. The process furthermore includes arranging the encapsulation material within the housing sidewalls.

The above-noted EXAMPLE may further include any one or a combination of more than one of the following EXAMPLES:

The process includes may include arranging the membrane structure above the power devices and the power wire bonds. The process also includes may include arranging the membrane structure between the housing sidewalls. The process further includes may include configuring and structuring the membrane structure and the housing sidewalls as a single component, such that the membrane structure is part of the housing sidewalls. The process in addition includes may include configuring and structuring the membrane structure and the housing sidewalls as separate components. The process moreover includes may include configuring and structuring the membrane structure and the housing sidewalls with a same material. The process also includes may include configuring and structuring the membrane structure and the housing sidewalls are with different materials having different material properties. The process further includes, may include configuring and structuring the membrane structure and the encapsulation material with different materials having different material properties. The process in addition includes may include arranging the membrane structure between at least two of the power contacts. The process moreover includes may include arranging the encapsulation material at least partially on the power devices and/or the power wire bonds. The process also includes may include dispensing the encapsulation material with a dispensing device at least partially on the power devices and/or the power wire bonds. The process further includes may include arranging the encapsulation material to extend from the power devices and/or the power wire bonds up to the membrane structure. The process in addition includes may include arranging the encapsulation material to extend from the power devices into the membrane structure, through the membrane structure, and/or above the membrane structure. The process moreover includes may include arranging the encapsulation material to extend from the power devices into the membrane structure and above the membrane structure. The process also includes where the encapsulation material may include an epoxy material. The process further includes may include arranging the membrane structure to occupy 20% 50% of a volume within the power module with respect to a volume of the encapsulation material within the power module. The process in addition includes may include configuring and structuring the membrane structure with stress reduction features and/or strain reduction features. The process moreover includes may include forming aperture portions in the membrane structure. The process also includes may include configuring and structuring the aperture portions as stress reduction features and/or strain reduction features. The process further includes may include arranging the encapsulation material to extend from the power devices and/or the power wire bonds into the aperture portions, through the aperture portions, and/or above the aperture portions. The process in addition includes may include arranging the encapsulation material to extend from the power devices and/or the power wire bonds into the aperture portions and above the aperture portions. The process moreover includes may include arranging the encapsulation material to extend from the at least one power substrate up to the aperture portions. The process also includes may include arranging the encapsulation material to extend from the at least one power substrate up to the aperture portions and into the aperture portions. The process further includes where the membrane structure may include an upper surface, a lower surface, and aperture surfaces; where the aperture surfaces define a shape and perimeter of the aperture portions; and where the aperture surfaces extend between the upper surface and the lower surface. The process in addition includes may include arranging the encapsulation material to extend from the power devices and/or the power wire bonds up to the lower surface of the membrane structure. The process moreover includes may include arranging the encapsulation material to extend from the power devices and/or the power wire bonds up to the aperture surfaces of the membrane structure. The process also includes may include arranging the encapsulation material to extend from the power devices and/or the power wire bonds up to the upper surface of the membrane structure.

One EXAMPLE: a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a dam structure and an encapsulation material. The process also includes filling the dam structure with a dam encapsulation material. The process furthermore includes configuring and structuring the dam encapsulation material and the encapsulation material with different materials having different material properties.

The above-noted EXAMPLE may further include any one or a combination of more than one of the following EXAMPLES:

The process includes may include dispensing a material with a dispensing device to form the dam structure. The process also includes may include dispensing with a dispensing device the dam encapsulation material to fill the dam structure. The process further includes where the dam encapsulation material may include an epoxy material; and where the encapsulation material may include a silicone material. The process in addition includes where the dam encapsulation material may include an epoxy material. The process moreover includes where the encapsulation material may include a silicone material. The process also includes may include: arranging the dam encapsulation material within the dam structure; and arranging the dam encapsulation material at least partially on the power devices, the power wire bonds, and/or signal connections. The process further includes where the dam structure may include but is not limited to RTV silicone (room-temperature-vulcanizing silicone) and/or a silicone epoxy composition. The process in addition includes may include arranging the dam structure around at least one of the power devices. The process moreover includes may include configuring and structuring the dam encapsulation material and the dam structure as stress reduction features and/or strain reduction features. The process also includes may include further: providing a housing having at least housing sidewalls; and configuring and structuring the encapsulation material within the housing sidewalls. The process further includes may include: arranging the dam structure on at least one power substrate; and arranging the dam structure to surround at least partially one or more implementations of the power devices, one or more implementations of signal connections, and/or one or more implementations of the power wire bonds. The process in addition includes may include: arranging the dam structure to extend along a surface of the at least one power substrate; and arranging the dam structure to extend up from the surface of the at least one power substrate. The process moreover includes may include arranging the encapsulation material at least partially on the dam structure.

One EXAMPLE: a process includes providing at least one power substrate. The process also includes arranging a plurality of power devices on at least one power substrate. The process furthermore includes providing power contacts. The process in addition includes providing power wire bonds. The process moreover includes providing a composite physical containment structure having a glob structure and an encapsulation material. The process also includes configuring and structuring the glob structure and the encapsulation material with different materials having different material properties. The process furthermore includes arranging a portion of the composite physical containment structure at least partially on the plurality of power devices, the power wire bonds, and/or the at least one power substrate.

The above-noted EXAMPLE may further include any one or a combination of more than one of the following EXAMPLES:

The process includes may include arranging the glob structure on at least one power substrate. The process also includes may include dispensing a material from a dispensing device to form the glob structure on at least one power substrate. The process further includes may include arranging the glob structure to at least partially surround one or more implementations of the power devices, signal connections, and/or the power wire bonds. The process in addition includes may include: arranging the glob structure to extend along a surface of the at least one power substrate; and arranging the glob structure to extend up from a surface of the at least one power substrate. The process moreover includes may include arranging the encapsulation material on the glob structure. The process also includes may include dispensing the encapsulation material with a dispensing device at least partially on the glob structure. The process further includes where the glob structure may include an epoxy material. The process in addition includes may include arranging the encapsulation material at least partially on a surface of the at least one power substrate. The process moreover includes where the encapsulation material may include a silicone material. The process also includes may include configuring and structuring the glob structure as a stress reduction feature and/or strain reduction feature. The process further includes where the plurality of power devices may include at least one power semiconductor device. The process in addition includes where the plurality of power devices may include at least one power semiconductor device having a Metal Oxide Field Effect Transistor (MOSFET). The process moreover includes where the plurality of power devices may include at least one power semiconductor device having a Silicon Carbide (SiC) Metal Oxide Field Effect Transistor (MOSFET). The process also includes where the plurality of power devices may include at least one power semiconductor device configured as a power component.

Accordingly, the disclosure has set forth an improved power module 100 having a physical containment to limit moisture ingress and/or provide improve thermal conductivity. Moreover, the disclosed power module 100 may be implemented in numerous topologies including a half-bridge configuration, a full-bridge configuration, a common source configuration, a common drain configuration, a neutral point clamp configuration, a three phase configuration, and the like. Applications of the power module 100 may include power applications including a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, and electric vehicles (EVs), a converter, and the like.

Aspects of the disclosure have been described above with reference to the accompanying drawings, in which aspects of the disclosure are shown. It will be appreciated, however, that this disclosure may, however, be embodied in many different forms and should not be construed as limited to the aspects set forth above. Rather, these aspects are provided so that this disclosure will be thorough and complete, and will fully convey the scope of the disclosure to those skilled in the art. Additionally, the various aspects described may be implemented separately. Moreover, one or more the various aspects described may be combined. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

1. A power module, comprising:
at least one power substrate;
a plurality of power devices on the at least one power substrate;
power contacts;
power wire bonds; and
a composite physical containment structure comprising a composite element and an encapsulation material,
wherein the composite element comprises a membrane structure, a dam structure and/or a glob structure; and
wherein a portion of the composite physical containment structure is arranged at least partially on the plurality of power devices, the power wire bonds, and/or the at least one power substrate.

2. The power module according to claim 1,
wherein the composite element comprises the membrane structure; and
wherein the membrane structure is arranged above the power devices and the power wire bonds.

3. The power module according to claim 2, further comprising a housing comprising at least housing sidewalls,
wherein the membrane structure is arranged between the housing sidewalls.

4. The power module according to claim 2, further comprising a housing comprising at least housing sidewalls,
wherein the membrane structure and the housing sidewalls are configured and structured as a single component, such that the membrane structure is part of the housing sidewalls.

5. The power module according to claim 2, further comprising a housing comprising at least housing sidewalls,
wherein the membrane structure and the housing sidewalls are configured and structured as separate components.

6. (canceled)

7. (canceled)

8. The power module according to claim 2, further comprising a housing comprising at least housing sidewalls,
wherein the encapsulation material is arranged within the housing sidewalls.

9. The power module according to claim 8, wherein the membrane structure and the encapsulation material comprise different materials comprising different material properties.

10. (canceled)

11. The power module according to claim 2, wherein the encapsulation material is arranged at least partially on the power devices and/or the power wire bonds.

12. (canceled)

13. The power module according to claim 2, wherein the encapsulation material extends from the power devices into the membrane structure, through the membrane structure, and/or above the membrane structure.

14. (canceled)

15. The power module according to claim 2, wherein the encapsulation material comprises an epoxy material.

16. (canceled)

17. The power module according to claim 2, wherein the membrane structure comprises stress reduction features and/or strain reduction features.

18. The power module according to claim 2, wherein the membrane structure comprises aperture portions arranged therein.

19.-28. (canceled)

29. The power module according to claim 1, wherein the composite element comprises the dam structure.

30. The power module according to claim 29, wherein the dam structure is filled with a dam encapsulation material.

31. The power module according to claim 29, further comprising a housing comprising at least housing sidewalls,
wherein the encapsulation material is arranged within the housing sidewalls.

32. The power module according to claim 30, wherein the dam encapsulation material and the dam structure are configured as stress reduction features and/or strain reduction features.

33. (canceled)

34. The power module according to claim 30, wherein the dam encapsulation material and the encapsulation material comprise different materials comprising different material properties.

35.-43. (canceled)

44. The power module according to claim 1, wherein the composite element comprises the glob structure.

45. The power module according to claim 44, wherein the glob structure is arranged on the at least one power substrate.

46. The power module according to claim 44, wherein the glob structure and the encapsulation material comprise different materials comprising different material properties.

47. The power module according to claim 44, wherein the glob structure at least partially surrounds one or more implementations of the power devices, signal connections, and/or the power wire bonds.

48. The power module according to claim 44, wherein the glob structure is configured as a stress reduction feature and/or strain reduction feature.

49.-119. (canceled)

120. A power module, comprising:
at least one power substrate;
a plurality of power devices on the at least one power substrate;
power contacts;
power wire bonds;
a housing comprising at least housing sidewalls; and
a composite physical containment structure comprising a membrane structure and an encapsulation material,
wherein the encapsulation material is arranged within the housing sidewalls.

121.-146. (canceled)

147. A power module, comprising:
at least one power substrate;
a plurality of power devices on the at least one power substrate;
power contacts;
power wire bonds; and
a composite physical containment structure comprising a dam structure and an encapsulation material,
wherein the dam structure is filled with a dam encapsulation material; and
wherein the dam encapsulation material and the encapsulation material comprise different materials comprising different material properties.

148.-158. (canceled)

159. A power module, comprising:
at least one power substrate;
a plurality of power devices on the at least one power substrate;
power contacts;
power wire bonds; and
a composite physical containment structure comprising a glob structure and an encapsulation material,
wherein the glob structure and the encapsulation material comprise different materials comprising different material properties.

160.-228. (canceled)
